(19) United States
(12) Patent Application Publication
(10) Pub. No.: US 2025/0212399 A1
(43) Pub. Date: Jun. 26, 2025

(54) SEMICONDUCTOR DEVICES HAVING ENHANCED CHANNEL STRUCTURES THEREIN AND METHODS OF MANUFACTURING THE SAME

(71) Applicant: Samsung Electronics Co., Ltd., Suwon-si (KR)

(72) Inventors: Seungyoon Kim, Suwon-si (KR); Kyeongjin Park, Suwon-si (KR); Changsup Lee, Suwon-si (KR)

(21) Appl. No.: 18/675,557

(22) Filed: May 28, 2024

(30) Foreign Application Priority Data
Dec. 20, 2023 (KR) 10-2023-0187470

(51) Int. Cl. H10B 41/27; H01L 29/04; H10B 43/27

(52) U.S. Cl. CPC H10B 41/27; H10B 43/27; H10D 62/40

(57) ABSTRACT

A semiconductor device includes a substrate, a stack structure having a plurality of spaced-apart gate electrodes therein and extending in a vertical direction perpendicular to an upper surface of the substrate, and a plurality of channel structures extending vertically within respective channel holes, which pass vertically through the stack structure. Each of the channel structures includes: (i) a channel layer having a first crystal structure, and extending from adjacent an upper end to adjacent a lower end of a corresponding one of the channel holes, (ii) a protruding region extending from adjacent the upper end of each of the channel holes in the vertical direction, protruding from the channel layer toward a central axis of each of the channel holes, and having a second crystal structure, and (iii) a central pad layer extending inside the protruding region and having a third crystal structure, which is different from the first crystal structure.

### REFERENCE TO PRIORITY APPLICATION

This application claims priority under 35 USC § 119 to Korean Patent Application No. 10-2023-0187470, filed Dec. 20, 2023, the disclosure of which is hereby incorporated herein by reference.

### BACKGROUND

The present inventive concept relates to integrated circuit devices and methods of fabricating the same and, more particularly, to data storage systems and methods of fabricating the same.

In a data storage system requiring data storage, a semiconductor device for storing high-capacity data may be required. Accordingly, methods for increasing data storage capacity of semiconductor devices are being researched. For example, as one method for increasing data storage capacity of a semiconductor device, a semiconductor device including memory cells arranged three-dimensionally, instead of memory cells arranged two-dimensionally, has been proposed to achieve higher integration with greater storage capacity and smaller layout footprint.

### SUMMARY

An aspect of the present inventive concept is to provide a semiconductor device having improved reliability.

An aspect of the present inventive concept is to provide a data storage system including a semiconductor device having improved reliability.

According to an aspect of the present inventive concept, a semiconductor device is provided that includes a substrate, a stack structure including gate electrodes spaced apart from each other in a vertical direction, perpendicular to an upper surface of the substrate, and channel structures extending vertically in channel holes passing through the stack structure vertically. Each of the channel structures includes a channel layer, which has a first crystal structure and is connected from an upper end to a lower end of each of the channel holes, a protruding region having a second crystal structure and extending from the upper end of each of the channel holes in the vertical direction and protruding from the channel layer toward a central axis of each of the channel holes, and a central pad layer extending inside the protruding region and having a third crystal structure, which is different from the first crystal structure.

According to an aspect of the present inventive concept, a data storage system includes a semiconductor storage device, which includes a first semiconductor structure including circuit elements, a second semiconductor structure extending on one surface of the first semiconductor structure, an input/output pad electrically connected to the circuit elements, and a controller that is electrically connected to the semiconductor storage device through the input/output pad and controls the semiconductor storage device. The second semiconductor structure includes a substrate, a stack structure including gate electrodes spaced apart from each other in a first direction, and perpendicular to an upper surface of the substrate, and channel structures extending vertically in channel holes passing through the stack structure vertically. Each of the channel structures includes a channel layer, which is connected from an upper end to a lower end of each of the channel holes and includes a single crystal conductive material, and a central pad layer extending from the upper end of each of the channel holes in the first direction to fill an internal space of the channel layer, and including a polycrystalline conductive material. A first thickness of the channel layer in a second direction, perpendicular to the first direction, and on the upper end of each of the channel holes is greater than a second thickness of the channel layer in the second direction on the lower end of each of the channel holes.

According to an aspect of the present inventive concept, a method of manufacturing a semiconductor device includes: forming a mold structure by alternately stacking interlayer insulating layers and sacrificial layers on a plate layer, forming channel holes passing through the mold structure, forming amorphous channel layers in the channel holes, forming a sacrificial buried layer in an internal space of the amorphous channel layers in the channel holes, to have a space that is spaced apart from an upper surface of the mold structure by a first depth, forming an amorphous seed layer on a side surface of the amorphous channel layers on the sacrificial buried layer, forming a metal layer on a side surface of the amorphous seed layers, performing metal-induced lateral crystallization (MILC) of the amorphous seed layer and the amorphous channel layer by heat treating/annealing, removing the metal layer and the sacrificial buried layer, forming a buried insulating layer in an internal space of the crystallized channel layers in the channel holes, to have a space that is spaced apart from the upper surface of the mold structure by a second depth, and forming a central pad layer in the space spaced of the second depth on the buried insulating layer.

According to a further aspect of the present inventive concept, an integrated circuit memory device is provided, which includes: a vertical stack of spaced-apart gate electrodes on an underlying substrate, and a plurality of semiconductor channel structures extending vertically through at least a portion of the vertical stack of spaced-apart gate electrodes. In addition, each of the channel structures may include: (i) a semiconductor channel layer having a first crystal structure, on a sidewall of a corresponding channel hole within the vertical stack of spaced-apart gate electrodes, (ii) a channel layer protrusion having a second crystal structure, on an upper end of the semiconductor channel layer, and (iii) a channel pad at least partially filling an upper end of the channel hole. And, in some embodiments, the channel pad may be electrically connected to the semiconductor channel layer via the channel layer protrusion, and have a third crystal structure different from the first crystal structure.

Furthermore, in some embodiments, the channel layer protrusion may have a ring shape when viewed from a plan layout perspective, and the channel pad may fill a circular-shaped opening within the channel layer protrusion. In some embodiments, a size of a crystal grain of the semiconductor channel layer is larger than a size of a crystal grain of the channel pad; likewise, a size of a crystal grain of the channel layer protrusion is larger than a size of a crystal grain of the channel pad. The semiconductor channel layer may consist essentially of single crystal silicon, whereas the channel pad may consist essentially of polycrystalline silicon. A buried insulating layer may be provided that substantially fills the channel hole and has an upper surface in contact with a lower surface of the channel pad.

### BRIEF DESCRIPTION OF THE DRAWINGS

The above and other aspects, features, and advantages of the present inventive concept will be more clearly understood from the following detailed description, taken in conjunction with the accompanying drawings, in which:

FIG. 1 is a schematic plan view of a semiconductor device according to example embodiments.

FIG. 2 is a schematic cross-sectional view of a semiconductor device according to example embodiments.

FIGS. 3A to 3C are partially enlarged views of a semiconductor device according to example embodiments.

FIG. 4 is a partially enlarged view schematically illustrating a semiconductor device according to example embodiments.

FIG. 5 is a partially enlarged view schematically illustrating a semiconductor device according to example embodiments.

FIG. 6 is a partially enlarged view schematically illustrating a semiconductor device according to example embodiments.

FIG. 7 is a partial enlarged view schematically illustrating a semiconductor device according to example embodiments.

FIG. 8 is a schematic cross-sectional view of a semiconductor device according to example embodiments.

FIG. 9 is a schematic cross-sectional view of a semiconductor device according to example embodiments.

FIG. 10 is a schematic cross-sectional view of a semiconductor device according to example embodiments.

FIG. 11 is a flowchart illustrating a method of manufacturing a semiconductor device according to example embodiments.

FIGS. 12 to 23 is schematic cross-sectional views illustrating a method of manufacturing a semiconductor device according to example embodiments.

FIG. 24 is a view schematically illustrating a data storage system including a semiconductor device according to example embodiments.

FIG. 25 is a perspective view schematically illustrating a data storage system including a semiconductor device according to an example embodiment.

FIG. 26 is a cross-sectional view schematically illustrating a semiconductor package according to an example embodiment.

### DETAILED DESCRIPTION

Hereinafter, preferred embodiments of the present inventive concept will be described with reference to the accompanying drawings. Hereinafter, it can be understood that terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated.

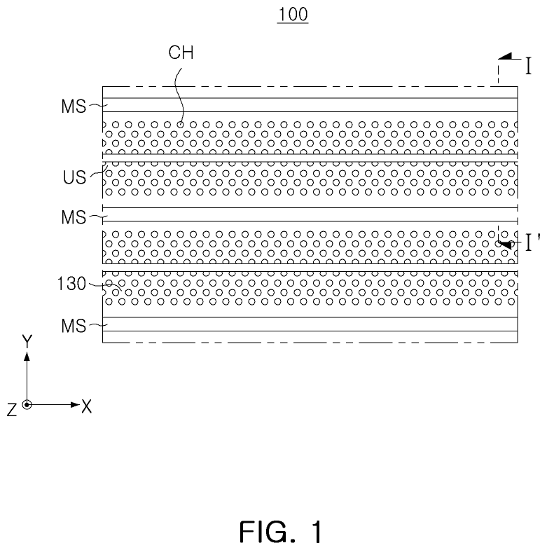

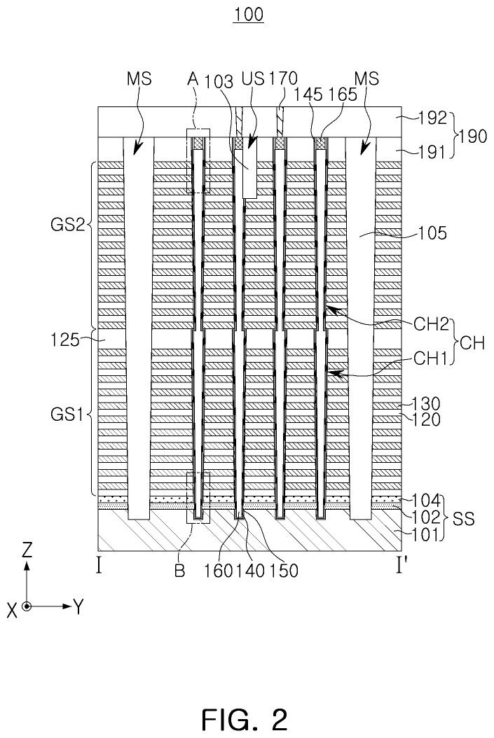

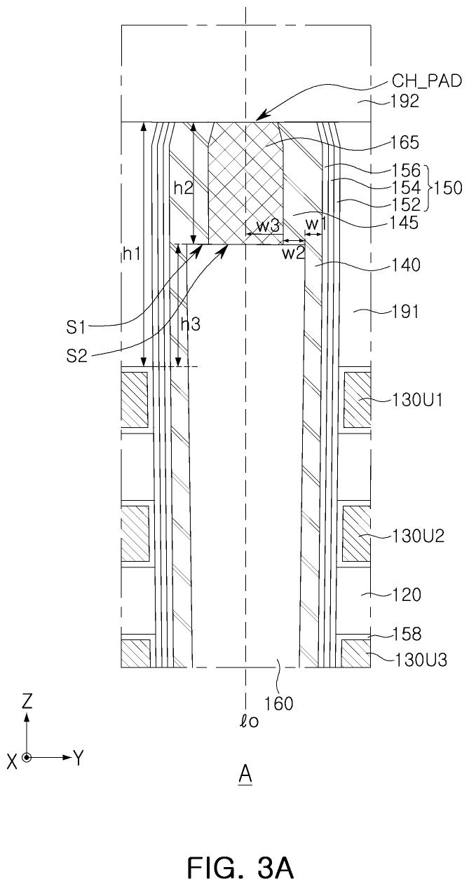

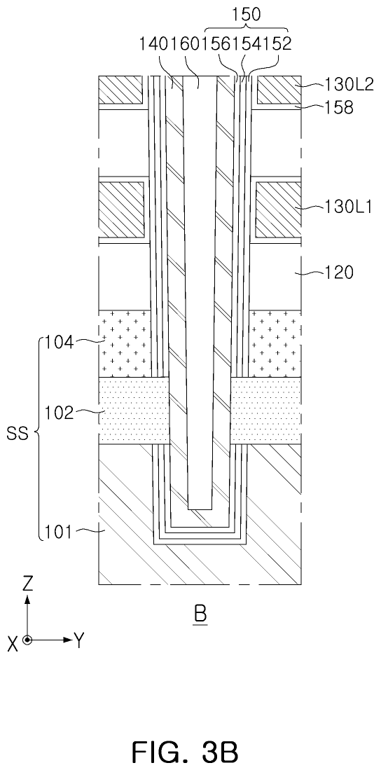

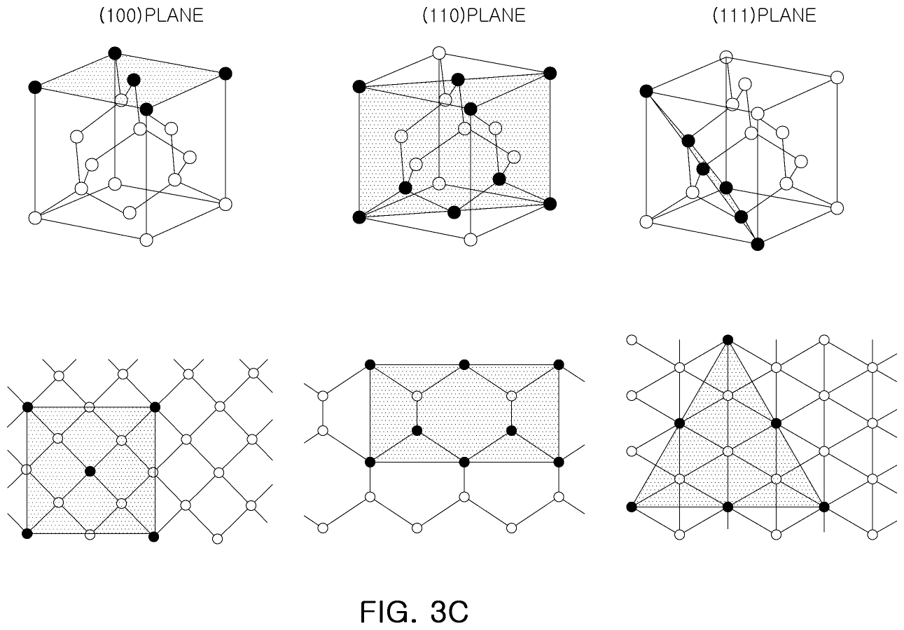

FIG. 1 is a schematic plan view of a semiconductor device according to example embodiments, and FIG. 2 is a schematic cross-sectional view of a semiconductor device according to example embodiments, taken along line I-I′ of FIG. 1. FIGS. 3A to 3B are partially enlarged views of a semiconductor device according to example embodiments. FIG. 3A illustrates an enlarged view of portion ‘A’ of FIG. 2, FIG. 3B illustrates an enlarged view of portion ‘B’ of FIG. 2, and FIG. 3C illustrates an example embodiment of a crystal plane of a semiconductor layer in FIGS. 3A and 3B.

Referring to FIGS. 1 to 3C, a semiconductor device 100 may include a source structure SS including a plate layer 101 and first and second horizontal conductive layers 102 and 104 on the plate layer 101, gate electrodes 130 stacked on the plate layer 101, interlayer insulating layers 120 alternately stacked with the gate electrodes 130 on the plate layer 101, channel structures CH that are arranged to penetrate first and second stack structures GS1 and GS2 of the gate electrodes 130, and respectively include a channel layer 140 and a multilayer channel pad CH_PAD, upper separation regions US penetrating a portion of the second stack structure GS2, separation regions MS extending to pass through the first and second stack structures GS1 and GS2, contact plugs 170 on the channel structures CH, and a cell region insulating layer 190 covering the gate electrodes 130 and the channel structures CH.

In the semiconductor device 100, one memory cell string may be formed around each of the channel structures CH, and a plurality of memory cell strings may be arranged in columns and rows in X and Y-directions. The plate layer 101 may have an upper surface extending laterally in the X and Y-directions. The plate layer 101 may include a semiconductor material, such as a group IV semiconductor, a group III-V compound semiconductor, or a group II-VI compound semiconductor. For example, the group IV semiconductor may include silicon, germanium, or silicon-germanium. The plate layer 101 may be provided as a bulk wafer, an epitaxial layer, a silicon-on-insulator (SOI) layer, a semiconductor-on-insulator (SeOI) layer, or the like.

The first and second horizontal conductive layers 102 and 104 may be stacked and disposed on the upper surface of the plate layer 101. The first and second horizontal conductive layers 102 and 104 may serve as source layers, and may form the source structure SS together with the plate layer 101. The source structure SS may function as a common source line of the semiconductor device 100. As illustrated in FIG. 3B, the first horizontal conductive layer 102 may be directly connected to the channel layer 140 around the channel layer 140. The first horizontal conductive layer 102 may partially extend in a Z-direction along the channel layer 140, and may be in contact with the channel layer 140.

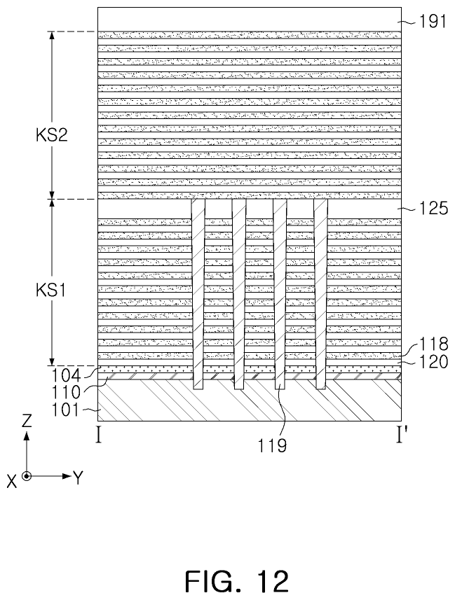

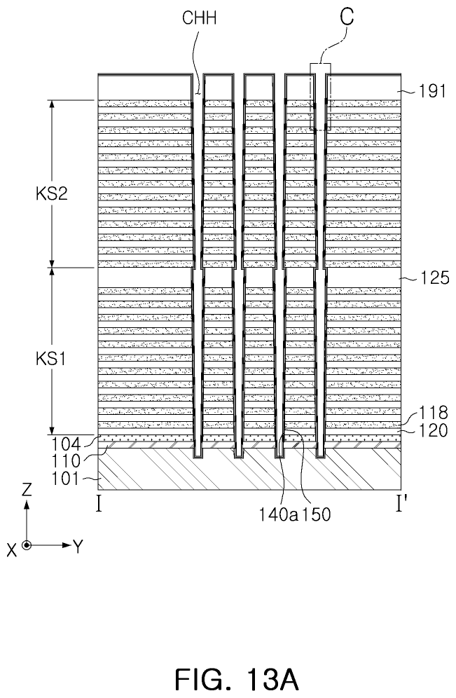

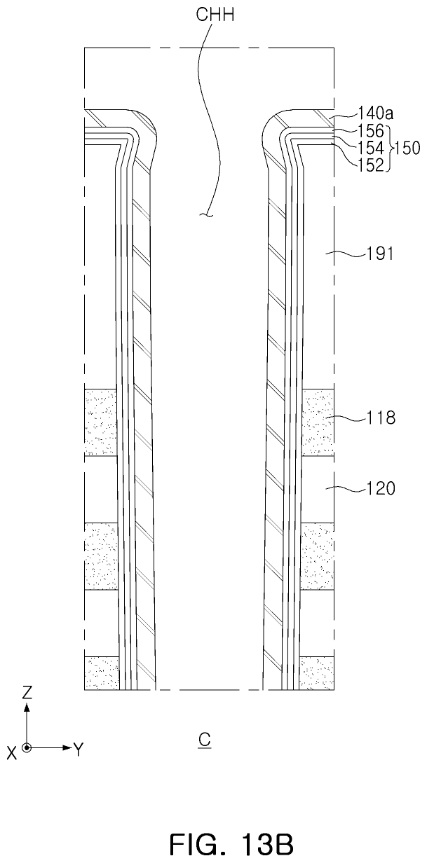

The first and second horizontal conductive layers 102 and 104 may include a semiconductor material, and may include, for example, polycrystalline silicon. In this case, at least the first horizontal conductive layer 102 may be a layer doped with impurities having a conductivity-type, identical to a conductivity-type of the plate layer 101. The second horizontal conductive layer 104 may be a doped layer, or may be a layer including impurities diffused from the first horizontal conductive layer 102, as an intrinsic semiconductor layer. A material of the second horizontal conductive layer 104 may not be limited to a semiconductor material, and the second horizontal conductive layer 104 may be replaced with an insulating layer depending on embodiments. In example embodiments, a relatively thin insulating layer may be interposed between an upper surface of the first horizontal conductive layer 102 and a lower surface of the second horizontal conductive layer 104. This may be a portion of a horizontal sacrificial layer 110 (see FIG. 12) that remains without being removed during a manufacturing process of the semiconductor device 100.

The gate electrodes 130 may be vertically spaced apart and stacked on the plate layer 101, to form the first and second stack structures GS1 and GS2. The gate electrodes 130 may include a lower gate electrode forming a gate of a ground select transistor, memory gate electrodes forming a plurality of memory cells, and upper gate electrodes forming gates of string select transistors. The number of the memory gate electrodes forming the memory cells may be determined depending on capacity of the semiconductor device 100. Depending on an embodiment, the upper and lower gate electrodes may be one or two or more, respectively, and may have the same or different structures as the memory gate electrodes. In example embodiments, the gate electrodes 130 may further include a gate electrode 130 disposed above the upper gate electrodes and/or below the lower gate electrode, and forming an erase transistor used for an erase operation using a gate induced leakage (GIDL) phenomenon. Additionally, some of the gate electrodes 130, for example, gate electrodes adjacent to the upper or lower gate electrodes, may be dummy gate electrodes.

The gate electrodes 130 may include a metal material, for example, tungsten (W). Depending on an embodiment, the gate electrodes 130 may include polycrystalline silicon or a metal silicide material. In example embodiments, the gate electrodes 130 may further include a diffusion barrier, and, for example, the diffusion barrier may include tungsten nitride (WN), tantalum nitride (TaN), titanium nitride (TiN), or a combination thereof.

The interlayer insulating layers 120 may be disposed between the gate electrodes 130. Like the gate electrodes 130, the interlayer insulating layers 120 may also be arranged to be spaced apart from each other in a direction, perpendicular to the upper surface of the plate layer 101. The interlayer insulating layers 120 may include an insulating material such as silicon oxide or silicon nitride.

The channel structures CH may form one memory cell string, respectively, and may be arranged in rows and columns on the plate layer 101 to be spaced apart from each other. The channel structures CH may be arranged to form a grid pattern in an X-Y plane or may be arranged in a zigzag shape in one direction. The channel structures CH may have a pillar shape filling a channel hole, may have an inclined side surface narrowing toward the plate layer 101 depending on an aspect ratio, and have a shape with a slightly smaller diameter at an upper end, as illustrated in FIG. 3A, but the present inventive concept is not limited thereto. As illustrated in FIG. 3A, a depth of a region in which the diameter of the upper end portion decreases may be very small, and a length of the decreased diameter may also be very small. Alternatively, by removing the upper end portion may be removed by a planarization process or the like during a process, such that side surfaces of the channel structures CH may be substantially inclined at a constant angle, but the present inventive concept is not limited thereto. As illustrated in FIGS. 3A and 3B, each of the channel structures CH may further include a channel dielectric layer 150 on an outer side surface of the channel layer 140, a channel buried insulating layer 160 inside the channel layer 140, and a multilayer channel pad CH_PAD in the upper end portion, in addition to the channel layer 140.

The channel layer 140 may be formed in an annular shape surrounding the channel buried insulating layer 160 therein. In some embodiments, the channel buried insulating layer 160 may be omitted, and the channel layer 140 may have a pillar shape such as a cylinder that fills an internal space of the channel hole. The channel layer 140 may include a semiconductor material such as silicon, and may be a single crystal structure.

The channel layer 140 may be a layer that may omit conductive impurities, such as P-type impurities or N-type dopant impurities, during the manufacturing process. For example, the channel layer 140 may be a layer that may not be intentionally doped with conductive impurities. In some embodiments, the channel layer 140 may further include N-type impurities diffused from a central pad layer 165 and the source structure SS in an upper region and/or a lower region thereof. For example, when the gate electrodes 130 include an erase gate electrode forming an erase transistor, N-type impurities may be further included in a region parallel to the erase gate electrode.

A channel layer 140 in one channel hole may be formed of the same material, and the channel layer 140 may have a high degree of crystallization. The channel layer 140 in one channel hole may have a single crystal structure formed of one crystal grain, or may have a single crystal-like structure. The “single crystal-like structure” means a structure that may be more than about 98% of a single crystal. The channel layer 140 may be formed by metal-induced lateral crystallization (MILC) using a metal silicide layer (not illustrated), and may have a single crystal structure or a single crystal-like structure.

In the present embodiment, crystal grains in the channel structures CH may have different crystal planes and sizes. A crystal plane of the channel layer 140 in each channel hole may be one of a (100) plane, a (110) plane, or a (111) plane, as illustrated in FIG. 3C. The fact that a crystal plane of the channel layer 140 is composed of a (100) plane, when viewed in plan, may be defined that a plurality of (100) planes are sequentially stacked in the Z-direction, a direction in which the channel structure CH extends, when viewed in plan. The fact that a crystal plane of the channel layer 140 is composed of a (110) plane, when viewed in plan, may be defined that a plurality of (110) planes are sequentially stacked in the Z-direction, a direction in which the channel structure CH extends, when viewed in plan, and the fact that a crystal plane of the channel layer 140 is composed of a (111) plane, when viewed in plan, may be defined that a plurality of (111) planes are sequentially stacked in the Z-direction, a direction in which the channel structure CH extends, when viewed in plan.

For example, a crystal plane of the channel layer 140 in one channel hole may be a (100) plane, and a crystal plane of the channel layer 140 in a different channel hole adjacent thereto may be a (110) plane. According to this, a continuous channel layer 140 filling each channel hole may have a configuration in which identical crystal planes are stacked, and may have excellent mobility of charge carriers therein. A direction in which crystallization-inducing metal particles are diffused may be changed depending on a crystal plane, and when the crystal plane is a (111) plane, the crystallization-inducing metal may easily move in a direction to which the channel structure CH extends during a MILC process, but the present inventive concept is not limited thereto. The metal silicide layer or metal particles after performing the MILC process may not remain in the channel layer 140, and may be subsequently removed by a gettering process, not to affect an operation of the channel layer 140.

In the present embodiment, the channel layer 140 may be crystallized by MILC using a metal silicide layer, and may include a protruding region 145 having an extended thickness in the upper end portion of the channel layer 140 to control an amount of the metal silicide layer. The protruding region 145 may be a region contacting a diffused metal layer ME for forming the metal silicide layer, and an amount of metal silicide may be adjusted depending on a length h2 and a width W2 of the protruding region 145.

Referring to FIG. 3A, the protruding region 145 may protrude in the channel hole toward a central axis [symbol] ₀ of the channel hole, and may have a ring shape surrounding the central pad layer 165. The protruding region 145 may extend in the Z-direction from an upper end of the channel structure CH to have a protrusion length h2, and may extend from an inner side surface of the channel layer 140 to have a second width W2 toward the central axis [symbol] ₀. The protrusion length h2 of the protruding region 145 may be smaller than a length of the channel structure CH in the Z-direction, and may be smaller than a length of the channel layer 140 in the Z-direction.

Therefore, when the channel layer 140 may be formed in an annular shape having a first width W1 from an upper end to a lower end thereof, the protruding region 145 may be formed to have the second width W2 from the inner side surface of the channel layer 140 toward the central axis [symbol] ₀. Therefore, the channel layer 140 may have a first thickness of the first width W1 uniformly in a main region passing through the stack structures GS1 and GS2, and the channel pad CH_PAD in the upper end portion of the channel hole may have a second thickness obtained by adding the first width W1 and the second width W2 of the protruding region 145.

An amount of the metal silicide layer formed during the process may be controlled according to the protrusion length h2 of the protrusion region 145, and this may be determined according to a length of the channel layer 140 in the Z-direction. For example, when gate electrodes 130 of the stack structures GS1 and GS2 are stacked in large quantities and a length of the channel layer 140 passing through them is very long, a large amount of metal silicide layer should be formed such that a channel layer 140 in one channel hole may be crystallized into a single crystal having one crystal grain. However, when an amount of metal silicide is insufficient, crystallization of the single crystal may be stopped in a portion of a length of the channel layer 140, and a portion thereof may exist as single crystals, and a remainder thereof may be amorphous or crystalline. Therefore, as a length of the channel layer 140 increases, the protruding region 145 may be formed longer to increase an amount of the metal silicide layer, to thereby crystallize all of the channel layer 140 in the channel hole into a single crystal having one crystal grain.

As illustrated in FIG. 3A, a level of a lower surface S1 of the protruding region 145 may be higher than a level of an upper surface of an uppermost gate electrode 130U1 among the gate electrodes 130. An upper end of the channel structure CH may be formed to protrude from an upper end of the uppermost gate electrode 130U1 by a first height h1, and the protruding region 145 may extend downward in the Z-direction by the protrusion length h2 from the upper end of the channel structure CH. In this case, the protrusion length h2 may be smaller than the first height h1. Therefore, the lower surface S1 of the protruding region 145 and the upper surface of the uppermost gate electrode 130U1 may be arranged to have a separation distance h3, and the separation distance h3 may be equal to a difference between the first height h1 and the protrusion length h2.

The central pad layer 165 may be buried and disposed in the channel layer 140 surrounded by the protruding region 145. The center pad layer 165 may be formed to have a predetermined length from the upper end of the channel layer 140 in the channel structure CH, and may include a portion contacting the protruding region 145 on a side surface thereof, and the predetermined length may be identical to the length h2, but the present inventive concept is not limited thereto. When the predetermined length of the center pad layer 165 is equal to the protrusion length h2, an inner side surface of the protruding region 145 of the channel layer 140 and an outer surface of the center pad layer 165 may be in contact with each other such that areas thereof are equal to each other. Therefore, a lower surface S2 of the center pad layer 165 may be located on a level, equal to a level of the lower surface S1 of the protruding region 145, and may form a coplanar surface. The central pad layer 165 may have a pillar shape symmetrical with respect to the channel central axis [symbol] ₀, and may have an inclined outer side surface such that a radius of an upper surface is greater than a radius W3 of the lower surface S2. A shortest distance from the channel center axis [symbol] ₀ to the outer side surface of the center pad layer 165, for example, the radius W3 of the lower surface S2, may be equal to or greater than a width W2 of the protruding region 145. The center pad layer 165 may be physically and electrically connected to the channel layer 140. The central pad layer 165 may include, for example, doped polycrystalline silicon.

Therefore, an area on which the center pad layer 165 is disposed in an upper end portion of the channel structure CH may be defined as the channel pad CH_PAD, and the channel pad CH_PAD may have a structure in which the protruding region 145 having a ring shape surrounds the center pad layer 165 in a central portion, and the channel layer 140 surrounds the protruding region. Therefore, when the channel structure CH is viewed in a cross-section, perpendicular to the plate layer 101, the channel pad CH_PAD may have a conductive stack structure of at least three layers, and, alternatively, may have a conductive stack structure of five layers. The conductive stack structure of at least three layers (channel layer/center pad layer/channel layer) refers that a channel layer 140 including protruding regions 145 forming a single crystal on both sides centered on the center pad layer 165 of polycrystalline silicon has been formed. The conductive stack structure of five layers refers that, on both sides of the central pad layer 150 of polycrystalline silicon, the protruding region 145 and the channel layer 140 are disposed with an interface therebetween to form a five-layer (channel layer/protruding region/center pad layer/protruding region/channel layer).

The channel dielectric layer 150 may be disposed between the gate electrodes 130 and the channel layer 140. The channel dielectric layer 150 may be disposed to cover inner side and bottom surfaces of the channel hole CHH on which the channel structure CH is disposed. The channel dielectric layer 150 may include a blocking layer 152, a charge storage layer 154, and a tunneling layer 156, sequentially stacked from the gate electrodes 130. The semiconductor device 100 may further include a horizontal blocking layer 158, and the horizontal blocking layer 158 may extend in the horizontal direction along the gate electrodes 130. In some implementations, horizontal blocking layer 158 may be omitted.

The blocking layer 152 and the horizontal blocking layer 158 may include silicon oxide (SiO₂), silicon nitride (Si₃N₄), silicon oxynitride (SiON), a high-K dielectric material, or a combination thereof. The charge storage layer 154 may be a charge trap layer or a floating gate conductive layer. The tunneling layer 156 may tunnel charges into charge storage layer 154, and may include, for example, silicon oxide (SiO₂), silicon nitride (Si₃N₄), silicon oxynitride (SiON), or combinations thereof.

The channel buried insulating layer 160 may be disposed to fill the channel hole below the protruding region 145 and below the center pad layer 165 in the channel layer 140. The channel buried insulating layer 160 may include an insulating material, and may include, for example, silicon oxide (SiO₂), silicon nitride (Si₃N₄), silicon oxynitride (SiON), or a combination thereof.

The channel layer 140, the channel dielectric layer 150, and the channel buried insulating layer 160 may be connected to each other between a first channel structure CH1 and a second channel structure CH2, and the protruding region 145 may be disposed only on an upper end of the second channel structure CH2. An intermediate interlayer insulating layer 125 having a relatively thick thickness may be further disposed between the first channel structure CH1 and the second channel structure CH2. Shapes of the interlayer insulating layers 120 and the intermediate interlayer insulating layer 125 may be changed in various embodiments.

The upper separation regions US may extend in the X-direction between adjacent separation regions MS in the Y-direction. The upper separation regions US may be disposed to penetrate some of gate electrodes 130U1 to 130U3, including the uppermost upper gate electrode 130U1, among the gate electrodes 130. As illustrated in FIG. 2, the upper separation regions US may, for example, separate a total of three gate electrodes 130U1 to 130U3 from each other in the Y-direction. The number of gate electrodes 130U1 to 130U3 separated by the upper separation regions US may be changed in various embodiments. The upper separation region US may be disposed across a portion of the channel structures CH. The upper separation regions US may have a predetermined width in the Y-direction, and may extend across the plurality of channel structures CH arranged in a zigzag matrix in the X-direction. Therefore, when a plurality of channel structures CH are arranged to have the same separation distance, the upper separation area US may extend across two consecutive rows of channel structures CH at the same time. The upper separation region US may be recessed in an upper portion of the two rows of channel structures CH, for example, a portion of the channel structure CH facing the three gate electrodes 130U1 to 130U3, and thus some of the channel structures CH may be removed. In this case, the channel structures CH may be depressed by a length, smaller than a radius of the channel structure CH, which may be from the channel center axis [symbol] ₀ to an inner wall of the channel hole. Therefore, the upper separation area US may not pass through the channel center axis [symbol] ₀ of the channel structure CH, and the channel structure CH may be arranged such that ½ or more of an upper surface thereof remains, but the present inventive concept is not limited thereto. The channel structures CH in which the upper separation region US is depressed may be effective channel structures that actually function as memory cells, rather than dummy channel structures. The upper separation regions US may include an upper separation insulating layer 103. The upper separation insulating layer 103 may include an insulating material, and may include, for example, silicon oxide, silicon nitride, or silicon oxynitride.

The separation regions MS may pass through the gate electrodes 130, the interlayer insulating layers 120, and the first and second horizontal conductive layers 102 and 104 to extend in the X-direction, and may be connected to the plate layer 101. As illustrated in FIG. 1, the separation regions MS may be arranged parallel to each other. The separation regions MS may separate the gate electrodes 130 from each other in the Y-direction. The separation regions MS may have a shape of which width decreases toward the plate layer 101 due to a high aspect ratio. The separation regions MS may include a separation insulating layer 105 disposed in a trench. The separation insulating layer 105 may include an insulating material, and may include, for example, silicon oxide, silicon nitride, or silicon oxynitride.

The contact plugs 170 may be disposed on the channel structures CH. The contact plugs 170 may have a cylindrical shape and, depending on the aspect ratio, may have inclined side surfaces of which width decreases toward the plate layer 101. The contact plugs 170 may electrically connect the channel structures CH to upper interconnection structures such as bit lines. The contact plugs 170 may be formed of a conductive material, and may include, for example, at least one of tungsten (W), aluminum (Al), or copper (Cu).

The cell region insulating layer 190 may have a plurality of layer structures, and a first cell region insulating layer 191 may be disposed to cover the gate electrodes 130 and pass through the separation regions MS and US and the channel structures CH, and a second cell region insulating layer 192 may be disposed on the first cell region insulating layer 191, and may be disposed to cover the separation regions MS and US and the channel structures CH. The cell region insulating layer 190 may be formed of an insulating material, and may include, for example, at least one of silicon oxide, silicon nitride, and silicon oxynitride.

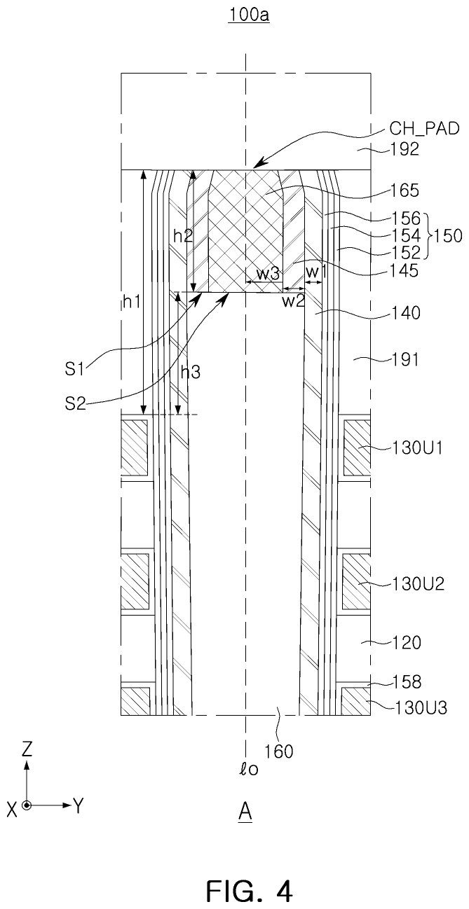

FIG. 4 is a partially enlarged view schematically illustrating a semiconductor device according to example embodiments. FIG. 4 illustrates an enlarged view of a portion corresponding to portion ‘A’ in FIG. 2. Referring to FIG. 4, a semiconductor device 100a may be identical to those of FIGS. 1 to 3C, except that a channel layer 140 and a protruding region 145 form different layers in channel structures CH. Specifically, the channel layer 140 and the protruding region 145 of the channel layer 140 may include individual single crystals having different crystal planes. As the channel layer 140 and the protruding region 145 are stacked using different stacking processes, they may be crystallized to have different crystal planes, depending on a process condition in each stacking process and a state of a lower surface at the time of stacking. Additionally, since diffusion directions of metal materials in the channel layer 140 and the protruding region 145 may be different, formed crystal planes may be different. For example, diffusion may mainly occur in a horizontal direction in the protruding region 145, and diffusion may mainly occur in the Z-direction and in a vertical direction, which may be extension directions of the channel layer 140, in the channel layer 140. Therefore, an interface may be formed between the protruding region 145 and the channel layer 140 under various conditions, and the channel layer 140 and the protruding region 145 may form crystal grains, respectively, and may be single crystallized. The crystal planes of the channel layer 140 and the protruding region 145 may be one of a (100) plane, a (110) plane, or a (111) plane, as illustrated in FIG. 3C. As an example, the channel layer 140 may have a (111) plane, but the present inventive concept is not limited thereto.

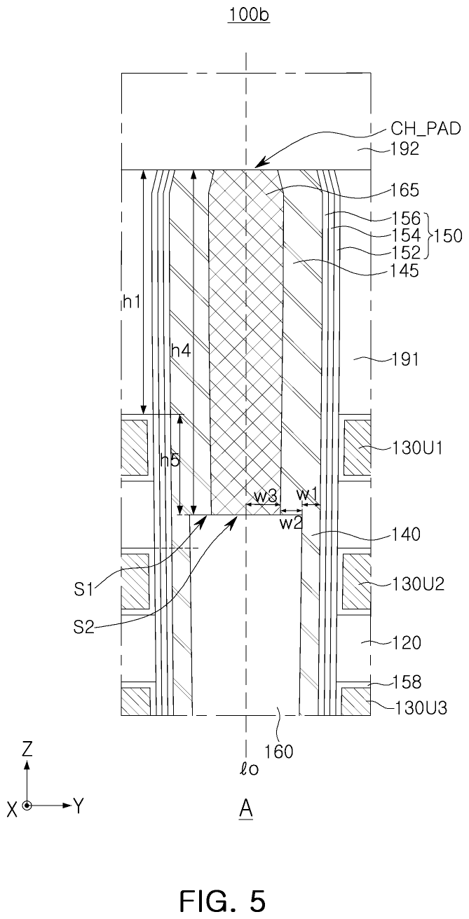

FIG. 5 is a partially enlarged view schematically illustrating a semiconductor device according to example embodiments. FIG. 5 illustrates an enlarged view of a portion corresponding to portion ‘A’ in FIG. 2. Referring to FIG. 5, a semiconductor device 100b may be identical to those of FIGS. 1 to 3C, except that a level of a lower surface S1 of a protruding region 145 of channel structures CH is lower than a level of an upper surface of an uppermost gate electrode 130U1 among gate electrodes 130.

As illustrated in FIG. 5, the level of the lower surface S1 of the protruding region 145 may be lower than a level of a lower surface of the uppermost gate electrode 130U1, and may be located on a level between upper and lower surfaces of an uppermost interlayer insulating layer 120. An upper end of the channel structure CH may be formed to protrude from the upper surface of the uppermost gate electrode 130U1 by a first height h1, and the protruding region 145 may extend downward in the Z-direction by a protrusion length h4 from the upper end of the channel structure CH. In this case, the protrusion length h4 may be greater than the first height h1, and a separation distance h5 between the protrusion length h4 and the first height h1 may be smaller than the first height h1, but the present inventive concept is not limited thereto. A central pad layer 165 may be buried and disposed in a channel layer 140 surrounded by the protruding region 145. A predetermined length of the center pad layer 165 may also be identical to the protrusion length h4, but the present inventive concept is not limited thereto. Even when the predetermined length of the center pad layer 165 is equal to the protrusion length h4, a shortest distance from a channel center axis [symbol] ₀ to an outer side surface, for example, a radius W3 of a lower surface S2 may be equal to or greater than a width W2 of the protruding region 145. In this manner, when the protrusion region 145 is formed long to have the protrusion length h4, since a larger amount of diffused metal material may be deposited, larger amounts of diffused metal material and silicide in an MILC process may be formed to achieve smooth crystallization up to a lower end of the channel structure CH.

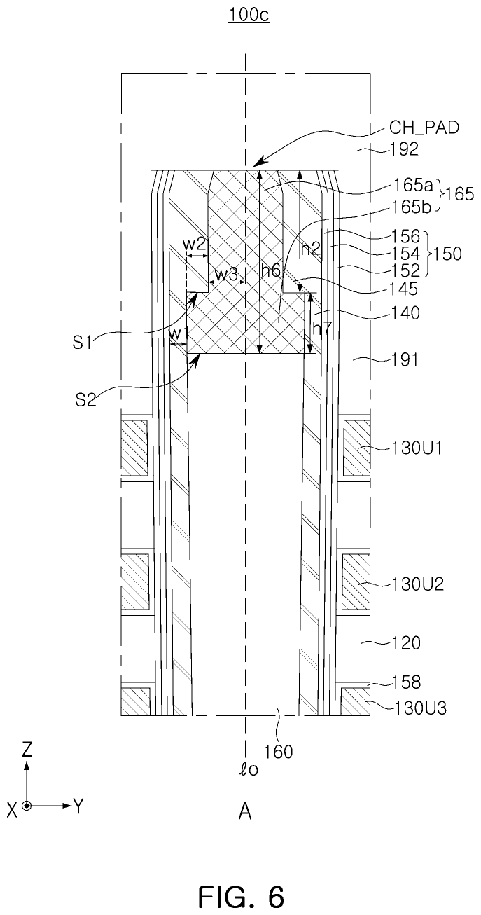

FIG. 6 is a partially enlarged view schematically illustrating a semiconductor device according to example embodiments. FIG. 6 illustrates an enlarged view of a portion corresponding to portion ‘A’ in FIG. 2. Referring to FIG. 6, a semiconductor device 100c may be identical to those of FIGS. 1 to 3C, except that a level of a lower surface S1 of a protruding region 145 of channel structures CH is different from a level of a lower surface S2 of a center pad layer 165.

As illustrated in FIG. 6, the level of the lower surface S1 of the protruding region 145 may be higher than the level of the lower surface S2 of the central pad layer 165. For example, the center pad layer 165 may include a pad portion 165a contacting a side surface of the protruding region 145, and an expansion portion 165b extending downward from the pad portion 165a and extending to cover the lower surface S1 of the protruding region 145. A length h7 of the extension portion 165b may be equal to a difference between a protrusion length h2 of the protruding region 145 and a length h6 of the central pad layer 165, and the length h7 of the extension portion 165b may be smaller than the protrusion length h2 of the protruding region 145, but the present inventive concept is not limited thereto. Therefore, a buried insulating layer 160 in a lower portion may only be in contact with the central pad layer 165 without contacting the protruding region 145. Contact between an upper surface of the buried insulating layer 160 and multiple layers may be minimized to minimize occurrence of cracks during deposition of the buried insulating layer 160.

The level of the lower surface S1 of the protruding region 145 may be higher than a level of an upper surface of an uppermost gate electrode 130U1, as illustrated in FIG. 3A, and the level of the lower surface S2 of the center pad layer 165 may also be higher than the level of the upper surface of the uppermost gate electrode 130U1, but the present inventive concept is not limited thereto.

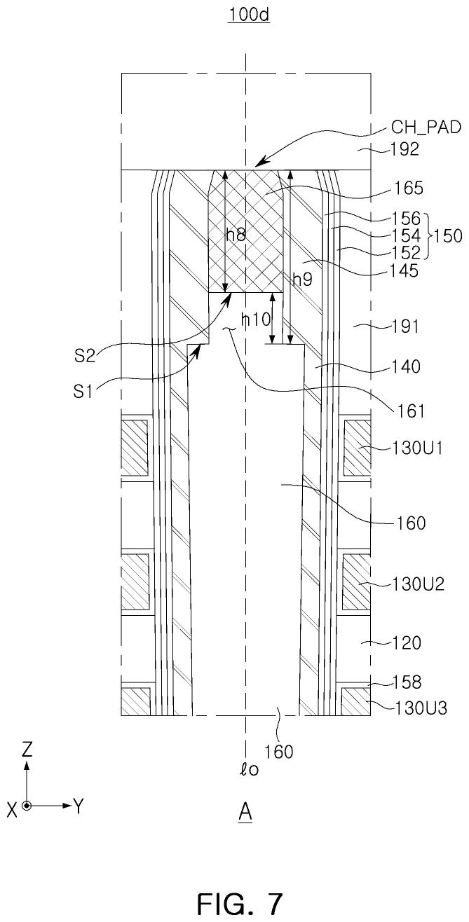

FIG. 7 is a partial enlarged view schematically illustrating a semiconductor device according to example embodiments. FIG. 7 illustrates an enlarged view of a portion corresponding to portion ‘A’ in FIG. 2. Referring to FIG. 7, a semiconductor device 100d may be identical to those of FIGS. 1 to 3C, except that a level of a lower surface S1 of a protruding region 145 of channel structures CH is different from a level of a lower surface S2 of a center pad layer 165.

As illustrated in FIG. 7, the level of the lower surface S1 of the protruding region 145 may be lower than the level of the lower surface S2 of the central pad layer 165. For example, the center pad layer 165 may be formed to have a length shorter than the protruding region 145, and a separation space 161 having a depression depth h10 may be formed between the lower surface S2 of the center pad layer 165 and the protruding region 145. The depression depth h10 of the separation space 161 may be equal to a difference between a length h9 of the protruding region 145 and a length h8 of the central pad layer 165, and the depression depth h10 may be smaller than the length h9 of the protruding region 145, but the present inventive concept is not limited thereto. Therefore, a buried insulating layer 160 in a lower portion may have a stepped structure on an upper end thereof, and may be in contact with the lower surfaces S1 and S2 of the protruding region 145 and the central pad layer 165. The buried insulating layer 160 may have a stepped structure on an upper end thereof, and may be formed to contact the protruding region 145 and the central pad layer 165 to bury the separation space 161, such that the central pad layer 165 and the protruding region 145 may be in contact with the buried insulating layer 160 with no space.

The level of the lower surface S1 of the protruding region 145 may be higher than a level of an upper surface of an uppermost gate electrode 130U1, as illustrated in FIG. 3A, and the level of the lower surface S2 of the center pad layer 165 may also be higher than the level of the upper surface of the uppermost gate electrode 130U1, but the present inventive concept is not limited thereto.

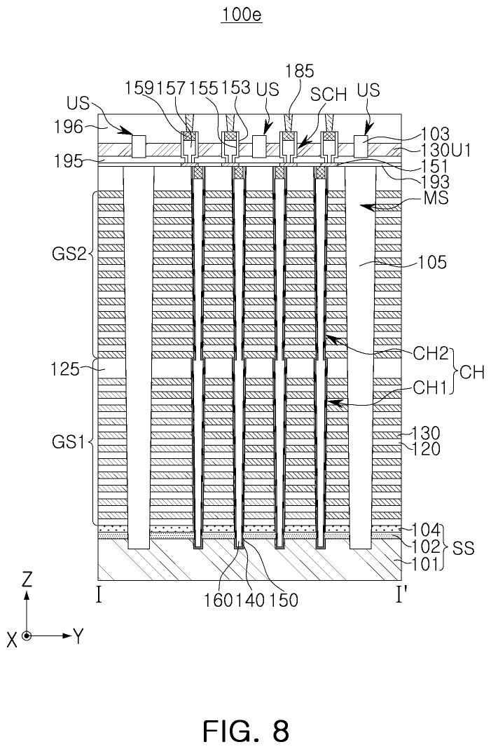

FIG. 8 is a schematic cross-sectional view of a semiconductor device according to example embodiments. Referring to FIG. 8, a semiconductor device 100e may be identical to those of FIGS. 1 to 3C, except that an upper channel structure SCH is further included on channel structures CH. Upper channel structures SCH may pass through a first upper gate electrode 130U1 to extend in the Z-direction, and may be respectively connected to the channel structures CH. The upper channel structures SCH may be respectively disposed on the channel structures CH, and may be offset from the channel structures CH in a horizontal direction, but the present inventive concept is not limited thereto.

As illustrated in FIG. 8, the upper channel structures SCH may include an upper channel layer 155, an upper gate dielectric layer 153, an upper channel buried insulating layer 157, and an upper channel pad 159, arranged in an upper channel hole, respectively. The upper channel layer 155 may be formed in an annular shape surrounding the upper channel buried insulating layer 157 therein. The upper channel layer 155 may be connected to a connection pad 151 in a lower portion, and may be electrically connected to a channel layer 140 of a channel structure CH in a lower portion through the connection pad 151.

In descriptions for materials of the upper channel layer 155, the upper gate dielectric layer 153, the upper channel buried insulating layer 157, and the upper channel pad 159, descriptions for a channel layer 140, a gate dielectric layer 150, a channel buried insulating layer 160, and a center pad layer 165, respectively, as described above, in a lower portion may be equally applied.

A horizontal insulating layer 193 may be disposed between channel structures CH in a lower portion and the upper channel structures SCH, and may extend horizontally. The horizontal insulating layer 193 may be disposed between a first upper gate electrode 130U1 and a first cell region insulating layer 191. The horizontal insulating layer 193 may be used as an etch stop layer when forming the upper channel structures SCH, and may also be a layer used when forming connection pads 151.

The horizontal insulating layer 193 may include an insulating material, and may include a material, different from a material of a third cell region insulating layer 196. The horizontal insulating layer 193 may be a hydrogen blocking layer, and may include a material that prevents or reduces diffusion of hydrogen (H). The horizontal insulating layer 193 may include a nitride, and may include, for example, at least one of SiN, SION, SiCN, or SiOCN.

The connection pads 151 may pass through the horizontal insulating layer 193 between channel structures CH in a lower portion and the upper channel structures SCH, and may electrically connect the channel layers 140 in the lower portion and upper channel layers 155. The connection pads 151 may be formed by partially removing the horizontal insulating layer 193, and may have upper surfaces coplanar with an upper surface of the horizontal insulating layer 193. The connection pads 151 may be disposed in a state in which a center pad layer 165 in a lower portion is partially recessed. Specific arrangement of the connection pads 151 may be changed in various embodiments. The connection pads 151 may include a conductive material, and may include, for example, polycrystalline silicon.

Upper separation regions US may extend in the X-direction between adjacent separation regions MS, as illustrated in FIG. 1. The upper separation regions US may pass through the first upper gate electrode 130U1 disposed in an uppermost portion of gate electrodes 130. The upper separation regions US may divide the first upper gate electrode 130U1 in the Y-direction, as illustrated in FIG. 8. Some of the upper separation regions US may be disposed on separation regions MS. Therefore, the upper separation regions US may not be formed to recess a portion of the channel structures CH, as illustrated in FIG. 2, but may be arranged to separate only the first upper gate electrode layer 130U1. The upper separation regions US may include an upper separation insulating layer 103, respectively. The upper separation insulating layer 103 may include an insulating material, and may include, for example, silicon oxide, silicon nitride, or silicon oxynitride.

A second horizontal insulating layer 195 may be disposed to cover stack structures GS1 and GS2. The second horizontal insulating layer 195 may be disposed on the horizontal insulating layer 193, the third cell region insulating layer 196 may be disposed on or above the second horizontal insulating layer 195, and may cover a side surface of the first upper gate electrode 130U1. The third cell region insulating layer 196 and the second horizontal insulating layer 195 may be formed of an insulating material or may be formed as a plurality of insulating layers. When the first and third cell region insulating layers 191 and 196 include the same material as interlayer insulating layers 120, interfaces with the interlayer insulating layers 120 may not be distinct.

In this manner, when a channel structure CH in a lower portion and the upper channel structure SCH are connected to each other, the channel structure CH in the lower portion may be the channel structure CH illustrated in FIGS. 1 to 3C, may include a protruding region 145 in an upper portion of the channel layer 140, and may be formed as a single crystal. Alternatively, a shape of the channel structure CH of FIGS. 4 to 7 may be applied.

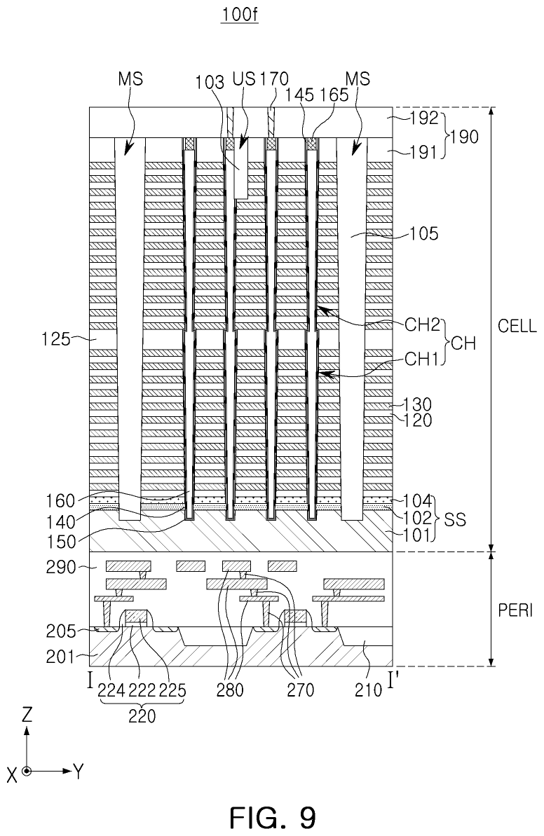

FIG. 9 is a schematic cross-sectional view of a semiconductor device according to example embodiments. Referring to FIG. 9, a semiconductor device 100f may include a memory cell region CELL and a peripheral circuit region PERI, stacked vertically. The memory cell region CELL may be disposed on the peripheral circuit region PERI. For example, in the semiconductor device 100 of FIG. 2, the peripheral circuit region PERI may be disposed on the plate layer 101 in a region not illustrated, or as in the semiconductor device 100f of the present embodiment, the peripheral circuit region PERI may be disposed below a plate layer 101. In example embodiments, the memory cell region CELL may be disposed below the peripheral circuit region PERI. Descriptions of the memory cell region CELL may be identically applied to those referring to FIGS. 1 to 3C.

The peripheral circuit region PERI may include a base substrate 201, and circuit elements 220, circuit contact plugs 270, and circuit interconnection lines 280, arranged on the base substrate 201. The base substrate 201 may have an upper surface extending in the X and Y-directions. Device isolation layers 210 may be formed on the base substrate 201 to define an active region. Source/drain regions 205 including impurities may be disposed in a portion of the active region. The base substrate 201 may include a semiconductor material, such as a group IV semiconductor, a group III-V compound semiconductor, or a group II-VI compound semiconductor. The base substrate 201 may be provided as a bulk wafer or an epitaxial layer.

The circuit elements 220 may include a horizontal transistor. Each of the circuit elements 220 may include a circuit gate dielectric layer 222, a spacer layer 224, and a circuit gate electrode 225. The source/drain regions 205 may be disposed in the base substrate 201 on both sides of the circuit gate electrode 225.

A peripheral region insulating layer 290 may be disposed on the circuit element 220 on the base substrate 201. The circuit contact plugs 270 may pass through the peripheral region insulating layer 290, and may be connected to the source/drain regions 205. An electrical signal may be applied to the circuit element 220 by the circuit contact plugs 270. In a region not illustrated, the circuit contact plugs 270 may also be connected to the circuit gate electrode 225. The circuit interconnection lines 280 may be connected to the circuit contact plugs 270, and may be disposed as multiple layers.

In the semiconductor device 100f, the peripheral circuit region PERI may be manufactured first, and then the plate layer 101 of the memory cell region CELL may be formed thereon to manufacture the memory cell region CELL. The plate layer 101 may be formed to have the same size as the base substrate 201, or may be formed to have a smaller size than the base substrate 201. The memory cell region CELL and the peripheral circuit region PERI may be connected to each other in a region not illustrated. For example, one end of the gate electrode 130 in the Y-direction may be electrically connected to the circuit elements 220. In this manner, a configuration in which the memory cell region CELL and the peripheral circuit region PERI are vertically stacked may be applied to other embodiments.

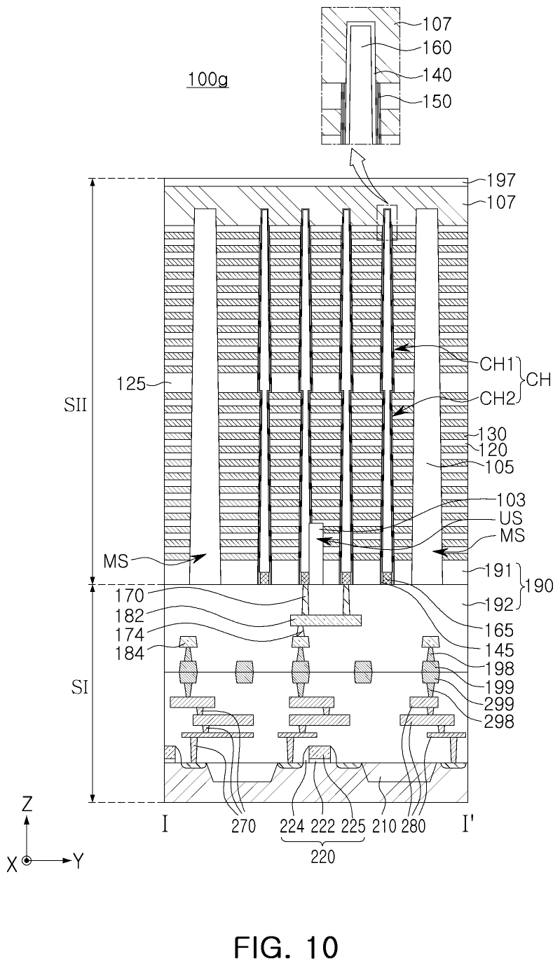

FIG. 10 is a schematic cross-sectional view of a semiconductor device according to example embodiments. Referring to FIG. 10, a semiconductor device 100g may include a first semiconductor structure SI and a second semiconductor structure SII, bonded using a wafer bonding method. A description of the peripheral circuit region PERI described above with reference to FIG. 9 may be applied to the first semiconductor structure SI. The first semiconductor structure SI may further include first bonding vias 298 and first bonding pads 299, which may be bonding structures. The first bonding vias 298 may be disposed on uppermost circuit interconnection lines 280, and may be connected to circuit interconnection lines 280. At least a portion of the first bonding pads 299 may be connected to the first bonding vias 298 on the first bonding vias 298. The first bonding pads 299 may be connected to second bonding pads 199 of the second semiconductor structure SII. The first bonding pads 299, together with the second bonding pads 199, may provide an electrical connection path for bonding the first semiconductor structure SI and the second semiconductor structure SII. The first bonding vias 298 and the first bonding pads 299 may include a conductive material, and may include, for example, copper (Cu). For the second semiconductor structure SII, unless otherwise specified, the descriptions referring to FIGS. 1 to 3A may be equally applied.

In the semiconductor device 100g of FIG. 10, a plate layer 101 and first and second horizontal conductive layers 102 and 104 on the plate layer 101 may be removed, and instead a conductive plate layer 107 may be stacked and disposed on a plurality of gates structures GS1 and GS2. The conductive plate layer 107 may serve as a source layer, and may form the source structure SS of FIG. 2. The source structure SS may function as a common source line of the semiconductor device 100g. As illustrated in the enlarged view of FIG. 10, the conductive plate layer 107 may be directly connected to a channel layer 140 around the channel layer 140. The conductive plate layer 107 may partially extend in the Z-direction along the channel layer 140, and may be in contact with the channel layer 140.

The conductive plate layer 107 may include a semiconductor material, such as a group IV semiconductor, a group III-V compound semiconductor, or a group II-VI compound semiconductor. For example, the group IV semiconductor may include silicon (Si), germanium (Ge), or silicon-germanium (SiGe). For example, the conductive plate layer 107 may include a doped polycrystalline silicon layer having an N-type conductivity-type, but the present inventive concept is not limited thereto. According to an example embodiment, the conductive plate layer 107 may be formed to have a large thickness to cover channel structures CH, but the present inventive concept is not limited thereto.

In each of the channel structures CH, a gate dielectric layer 150 may be removed on the channel layer 140, and a portion of the channel layer 140 may be exposed and directly connected to the conductive plate layer 107. According to an example embodiment, an exposed uppermost end of the channel layer 140 may be in direct contact with the conductive plate layer 107 on side and upper surfaces of the channel structures CH.

The second semiconductor structure SII may further include first and second cell interconnection lines 182 and 184 and a via 174, which may be interconnection structures, and second bonding vias 198 and second bonding pads 199, which may be bonding structures. The second semiconductor structure SII may further include a protective layer 197 covering an upper surface of the conductive plate layer 107.

The first cell interconnection line 182 may be connected to contact plugs 170, and the via 174 may connect the first and second cell interconnection lines 182 and 184 to each other. In embodiments, the number and arrangement of contact plugs, vias, and interconnection lines forming the interconnection structure may be changed. The first and second cell interconnection lines 182 and 184 and the via 174 may be formed of a conductive material, and may include, for example, at least one of tungsten (W), aluminum (Al), or copper (Cu).

The second bonding vias 198 and the second bonding pads 199 may be disposed below lowermost second cell interconnection lines 184. The second bonding vias 198 may be connected to the second cell interconnection lines 184 and the second bonding pads 199, and the second bonding pads 199 may be bonded to the first bonding pads 299 of the first semiconductor structure SI. The second bonding vias 198 and the second bonding pads 199 may include a conductive material, and may include, for example, copper (Cu).

The first semiconductor structure SI and the second semiconductor structure SII may be to be bonded in copper (Cu)-copper (Cu) bonding by the first bonding pads 299 and the second bonding pads 199. In addition to the copper (Cu)-copper (Cu) bonding, the first semiconductor structure SI and the second semiconductor structure SII may be additionally bonded by dielectric-dielectric bonding. The dielectric-dielectric bonding may be bonding by dielectric layers forming a portion of each of the peripheral region insulating layer 290 and the cell region insulating layer 190, and surrounding each of the first bonding pads 299 and the second bonding pads 199. As a result, the first semiconductor structure SI and the second semiconductor structure SII may be bonded without a separate adhesive layer.

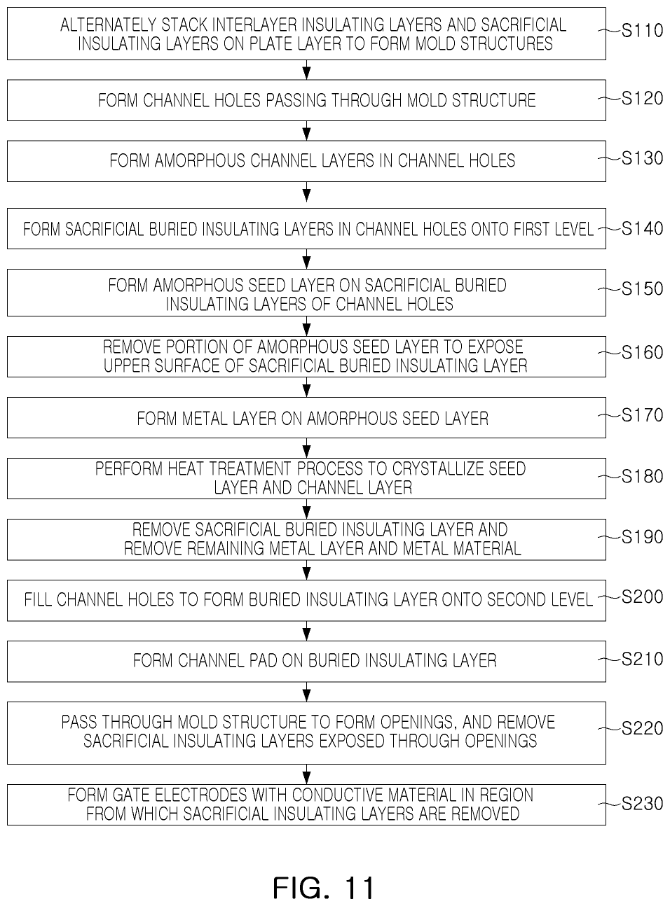

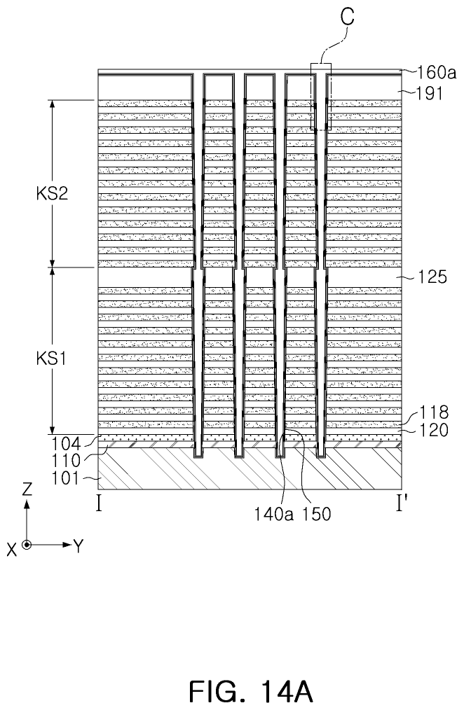

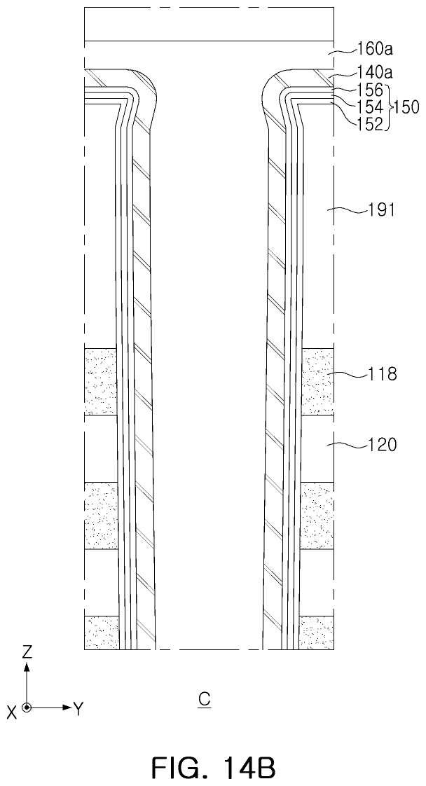

FIG. 11 is a flowchart illustrating a method of manufacturing a semiconductor device according to example embodiments, and FIGS. 12 to 23 is schematic cross-sectional views illustrating a method of manufacturing a semiconductor device according to example embodiments. FIGS. 13A, 14A, 15A, 16A, 17A, 18A, 19A, 20A, 21A, 12, 22, and 23 illustrate regions corresponding to the regions illustrated in FIG. 2, whereas FIGS. 13B, 14B, 15B, 16B, 17B, 18B, 19B, 20B, and 21B are enlarged views illustrating portions ‘C’ of FIGS. 13A, 14A, 15A, 16A, 17A, 18A, 19A, 20A, and 21A.

Referring to FIGS. 11 and 12, sacrificial insulating layers 118 and interlayer insulating layers 120 may be alternately stacked to form first and second mold structures KS1 and KS2 (S110). Specifically, a horizontal sacrificial layer 110 and a second horizontal conductive layer 104 may be first formed on a plate layer 101, the first mold structure KS1 may be formed, vertical sacrificial layers 119 penetrating the first mold structure KS1 may be then formed, and the second mold structure KS2 may be formed.

The horizontal sacrificial layer 110 may include a plurality of layers including different materials. The horizontal sacrificial layer 110 may be layers to be replaced with a first horizontal conductive layer 102 (see FIG. 2) by a subsequent process. For example, the horizontal sacrificial layer 110 may include a first layer and a third layer, formed of a material, identical to a material of the interlayer insulating layers 120, and may further include a second layer formed of a material, identical to a material of the sacrificial insulating layers 118, and disposed between the first layer and the third layer. The second horizontal conductive layer 104 may be formed on the horizontal sacrificial layer 110.

The sacrificial insulating layers 118 may be a layer to be replaced with gate electrodes 130 (see FIG. 2) by a subsequent process. The sacrificial insulating layers 118 may be formed of a material, different from the material of the interlayer insulating layers 120, and may be formed of a material that may be etched with etch selectivity under specific etching conditions with respect to the interlayer insulating layers 120. For example, the interlayer insulating layer 120 may be formed of at least one of silicon oxide or silicon nitride, and the sacrificial insulating layers 118 may be formed of a material, different from the material of the interlayer insulating layer 120, and selected from silicon, silicon oxide, silicon carbide, and silicon nitride. An intermediate interlayer insulating layer 125 having a relatively thick thickness may be formed in an uppermost portion of the first mold structure KS1. In embodiments, thicknesses of the interlayer insulating layers 120 may not all be constant. Thicknesses of the interlayer insulating layers 120 and the sacrificial insulating layers 118, and the number of constituting films thereof may be changed from those illustrated.

The vertical sacrificial layers 119 may be formed in a region corresponding to the first channel structures CH1 of FIG. 2. The vertical sacrificial layers 119 may be formed by forming lower channel holes to penetrate the first mold structure KS1, depositing a material forming the vertical sacrificial layers 119 in the lower channel holes, and performing a planarization process. The vertical sacrificial layers 119 may include a material, different from the materials of the interlayer insulating layers 120 and the sacrificial insulating layers 118. For example, the vertical sacrificial layers 119 may include a semiconductor material such as polycrystalline silicon, a silicon-based insulating material, or a carbon-based material. Next, a first cell region insulating layer 191 covering a stack structure of the sacrificial insulating layers 118 and the interlayer insulating layers 120 may be formed.

Referring to FIGS. 11, 13A, and 13B, channel holes CHH passing through the first and second mold structures KS1 and KS2 may be formed (S120), and channel dielectric layers 150 and amorphous channel layers 140a may be formed in the channel holes CHH (S130). The channel holes CHH may be formed by anisotropically etching the first and second mold structures KS1 and KS2 using a mask layer. Due to a height of the stack structures KS1 and KS2, a sidewall of the channel holes CHH may not be perpendicular to an upper surface of the plate layer 101. The channel holes CHH may be formed to recess a portion of the plate layer 101, and an opening width may be partially reduced on an upper end as illustrated in FIG. 13B, but the present inventive concept is not limited thereto.

The channel dielectric layers 150 may be formed by sequentially depositing a blocking layer 152, a charge storage layer 154, and a tunneling layer 156 in the channel holes CHH. The channel dielectric layers 150 may be formed to have a uniform thickness using an atomic layer deposition (ALD) process or a chemical vapor deposition (CVD) process. The amorphous channel layers 140a may be formed on the channel dielectric layers 150 in the channel holes CHH. In this operation, the amorphous channel layers 140a may be formed of an amorphous semiconductor material such as amorphous silicon. At this stage, the amorphous channel layers 140a may not be doped with conductive impurities.

The forming amorphous channel layers 140a may include depositing the amorphous channel layers 140a by flowing a silicon source gas. For example, the silicon source gas may include at least one of monosilane (SiH₄), disilane (Si₂H₆), trisilane (Si₃H₈), or dichlorosilane (SiH₂Cl₂). The amorphous channel layers 140a may be deposited at a temperature of about 300 degrees to about 500 degrees. The amorphous channel layers 140a may be formed to have a first thickness, and may be deposited to conformally cover the first cell region insulating layer 191 and the gate dielectric layer 150 in the channel hole CHH. Therefore, the amorphous channel layers 140a in the channel hole CHH may have a first width W1, equal to the first thickness.

Referring to FIGS. 11, 14A, 14B, 15A, and 15B, sacrificial buried insulating layers 160a may be formed in the channel holes CHH (S140), and an amorphous seed layer 145a may be formed on the sacrificial buried insulating layers 160a (S150). The sacrificial buried insulating layers 160a may be formed to fill the channel holes CHH.

The sacrificial buried insulating layers 160a may be formed thick to fill the channel holes CHH and cover an upper surface of the first cell region insulating layer 191, and a portion of the sacrificial buried insulating layers 160a may be then removed from a level of the upper surface of the first cell region insulating layer 191 by a predetermined depth of the channel holes CHH. Therefore, the sacrificial buried insulating layers 160a in each of the channel holes CHH may be disposed only up to a first level, which may be a protrusion length h2 of a protruding region 145 of the channel layer 140, and a space may be formed on an upper end of the channel hole CHH.

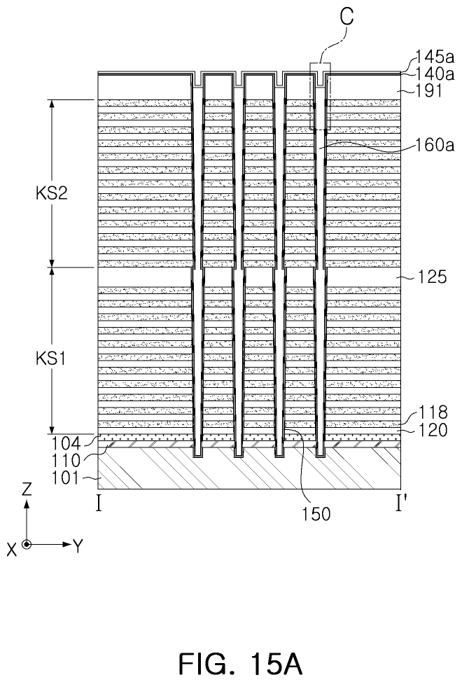

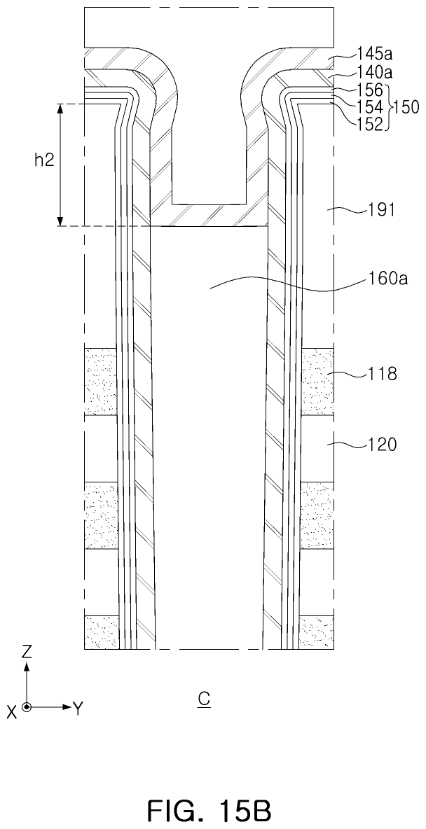

As illustrated in FIGS. 15A and 15B, the amorphous seed layer 145a may be formed along the space on the upper end of the channel hole CHH on the sacrificial buried insulating layers 160a.

The amorphous seed layer 145a may be formed on the amorphous channel layers 140a and the sacrificial buried insulating layers 160a in the channel holes CHH, and may extend outside the channel holes CHH such that the amorphous seed layer 145a may also be stacked on the amorphous channel layers 140a even on the first cell region insulating layer 191. In this operation, the amorphous seed layer 145a may be formed of an amorphous semiconductor material such as amorphous silicon. In this operation, the amorphous seed layer 145a may not be doped with conductive impurities.

The amorphous seed layer 145a may be deposited by flowing a silicon source gas. For example, the silicon source gas may include at least one of monosilane (SiH₄), disilane (Si₂H₆), trisilane (Si₃H₈), or dichlorosilane (SiH₂Cl₂). The amorphous seed layer 145a may be deposited at a temperature of about 300 degrees to about 500 degrees. The silicon source gas forming the amorphous seed layer 145a may be identical to the silicon source gas forming the amorphous channel layers 140a, but the present inventive concept is not limited thereto. Additionally, for conductivity, the amorphous seed layer 145a may be formed to partially include conductive impurities, but the present inventive concept is not limited thereto. The amorphous seed layer 145a may be formed to have a second thickness, and may be deposited to conformally cover the amorphous channel layers 140a and the sacrificial buried insulating layers 160a. Therefore, the amorphous seed layer 145a in the channel hole CHH may have a second width W2, equal to the second thickness. The second width W2 may be equal to or greater than the first width W1.

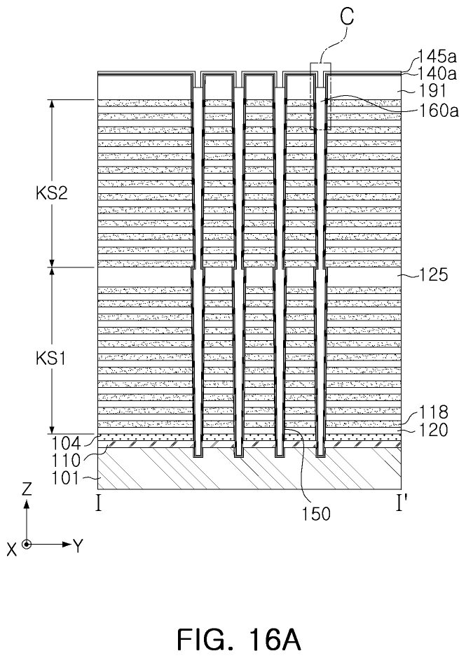

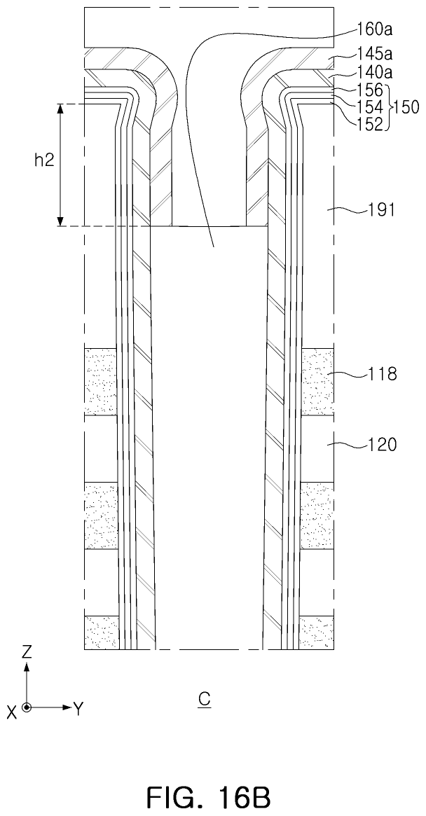

Referring to FIGS. 11, 16A, and 16B, a portion of the amorphous seed layer 145a may be removed to expose a portion of the sacrificial buried insulating layer 160a (S160). In the operation of removing a portion of the amorphous seed layer 145a, post-etching may be to perform to remove a bottom surface of the amorphous seed layer 145a in the channel hole CHH, for example, an upper surface of the sacrificial buried insulating layer 160a. The upper surface of the sacrificial buried insulating layer 160a may be exposed by selectively removing only the amorphous seed layer 145a. Therefore, the amorphous seed layer 145a may remain only on a side surface of the channel hole CHH on the sacrificial buried insulating layer 160a, forming a shape of the protruding region 145 of FIG. 2.

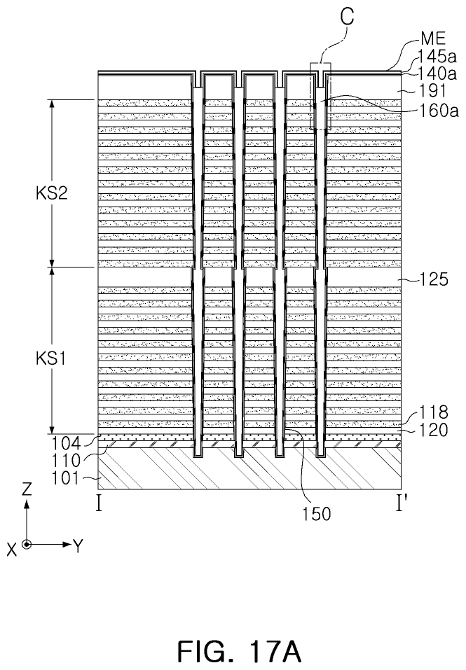

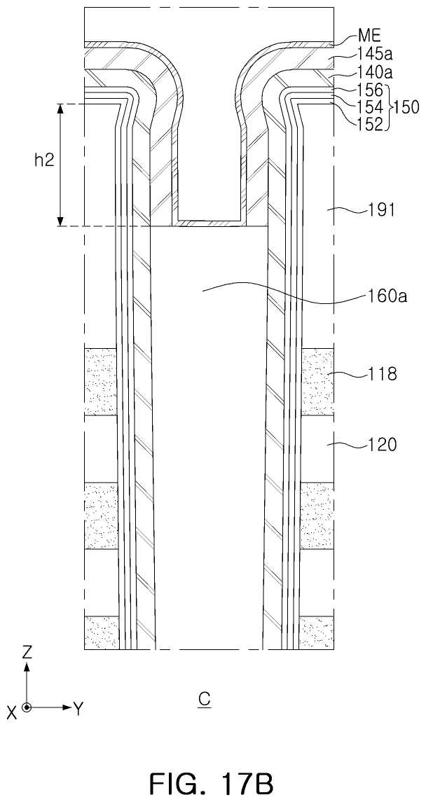

Referring to FIGS. 11, 17A, and 17B, a metal layer ME may be formed on the amorphous seed layer 145a and the sacrificial buried insulating layer 160a (S170). The metal layer ME may be formed to conformally cover an upper portion of the amorphous seed layer 145a on the upper surface of the first cell region insulating layer 191, and an upper portion of the amorphous seed layer 145a and an upper portion of the sacrificial buried insulating layer 160a in the channel hole CHH. The metal layer ME may include, for example, nickel (Ni), titanium (Ti), cobalt (Co), tungsten (W), platinum (Pt), palladium (Pd), or a combination thereof.

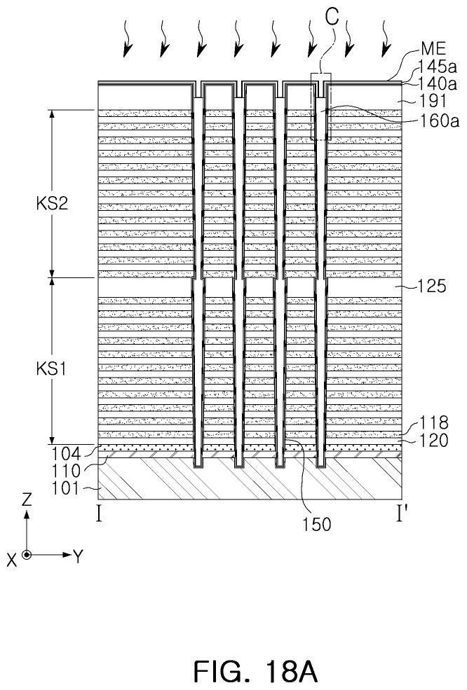

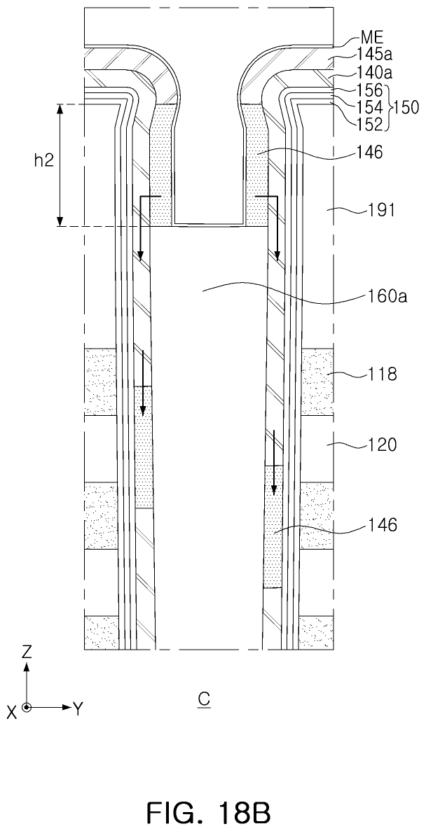

Referring to FIGS. 11, 18A and 18B, heat/annealing treatment may be performed on the metal layer ME on the amorphous seed layer 145a and the sacrificial buried insulating layer 160a to crystallize the amorphous seed layer 145a and the amorphous channel layer 140a (S180).

To inject metal particles from the metal layer ME into the amorphous seed layer 145a and the amorphous channel layer 140a, metal elements may be injected into the amorphous seed layer 145a by applying heat to a temperature of about 200 degrees to about 300 degrees. Thereafter, heat treatment may be performed at a temperature of about 400 degrees to about 500 degrees to form metal silicide layers 146 having a composition of MSi₂ (where M is a metal element) in the amorphous seed layer 145a. The metal silicide layer 146 may include a semiconductor element and a metal element. The metal silicide layer 146 may include, for example, nickel silicide (NiSi₂), titanium silicide (TiSi₂), cobalt silicide (CoSi₂), tungsten silicide (WSi₂), platinum silicide (PtSi₂), palladium silicide (PdSi₂), or other metal silicide, and in this case, germanium (Ge) or silicon germanium (SiGe) may be included instead of silicon (Si). The metal silicide layer 146 may be, for example, nickel silicide represented by NiSi₂.

Next, heat treatment may be continuously performed to crystallize the amorphous seed layer 145a and the amorphous channel layer 140a into a single crystal while the metal silicide layers diffuse in the Z-direction along the amorphous channel layer 140a from the amorphous seed layer 145a. The crystallization using this metal-induced lateral crystallization (MILC) method may proceed from an upper end of the amorphous seed layer 145a and an upper end of the amorphous channel layer 140a to lower ends thereof in the Z-direction, and the amorphous seed layer 145a and the amorphous channel layer 140a may have a single crystal or a single crystal-like structure. The heat treatment process may be performed at a temperature of about 800 degrees or more, for example, about 800 degrees to about 1000 degrees, but the present inventive concept is not limited thereto.

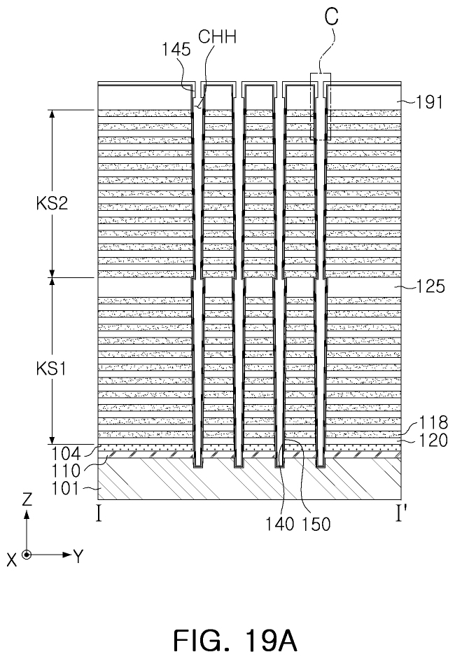

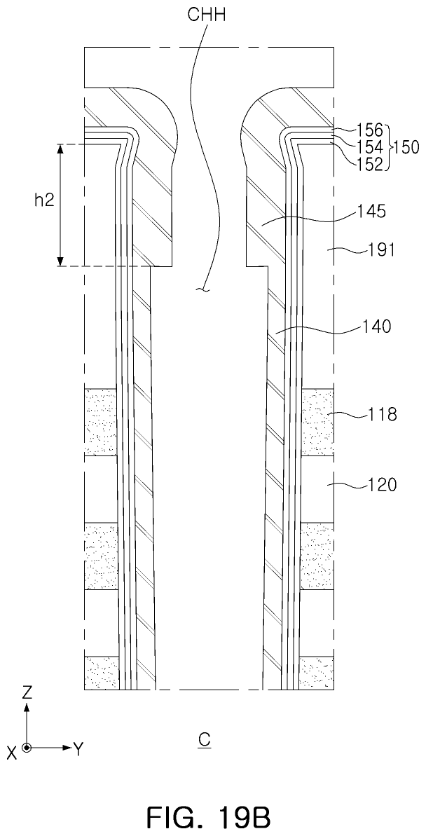

Referring to FIGS. 11, 19A, and 19B, a remaining portion of the metal layer ME may be removed, and the sacrificial buried insulating layer 160a may be removed to form a space in the channel hole CHH (S190). Specifically, a gettering process for removing a remaining portion of the metal layer ME or a remaining portion of the metal silicide layer 146 remaining in the channel hole CHH to remove all the metal particles may be performed. Gettering may be provided in various manners. For example, after depositing an amorphous material layer on a channel layer 140, heat treatment may be performed again to induce the remaining metal particles to diffuse into the amorphous material layer. When all the remaining metal particles diffuse into the amorphous material layer, all the metal particles remaining in the channel layer 140 and a protruding region 145 may be removed by removing the amorphous material layer. The gettering process may be modified in various manners, but the present inventive concept is not limited thereto. After all metal particles in the channel layer 140 and the protruding region 145 are removed, all of the sacrificial buried insulating layer 160a may be removed, from the exposed upper surface of the sacrificial buried insulating layer 160a. Therefore, a space may be formed in the channel hole CHH, and the channel layer 140 and the protruding region 145 may be disposed on an outermost surface in a single crystal state.

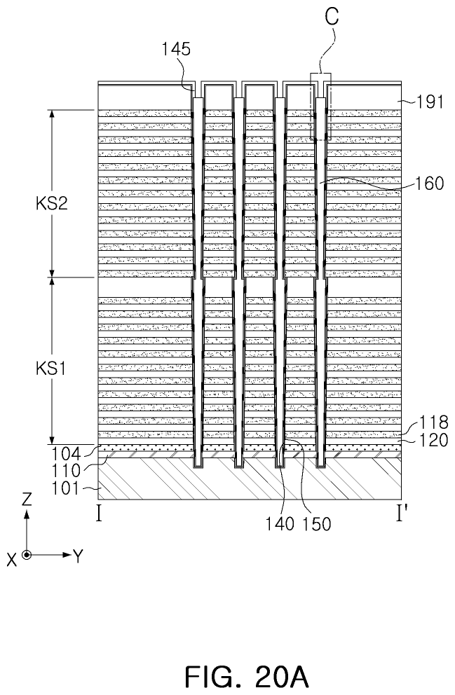

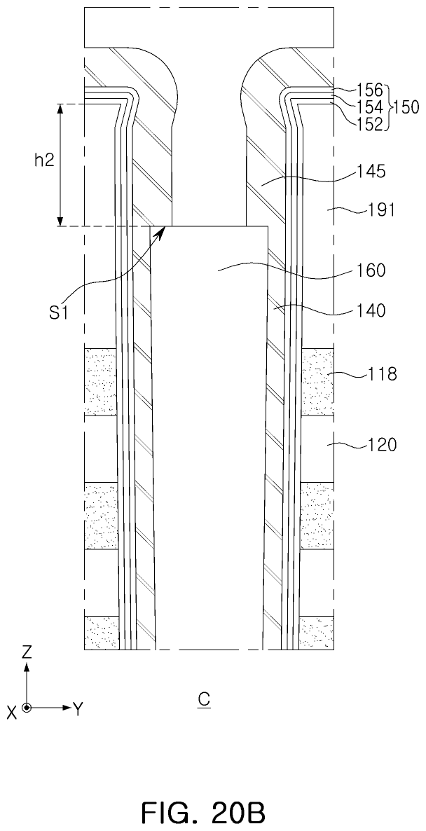

Referring to FIGS. 11, 20A, and 20B, buried insulating layers 160 may be formed in the channel holes CHH (S200). The buried insulating layers 160 may be formed to fill the channel holes CHH. The buried insulating layers 160 may be formed thick to fill the channel holes CHH and cover the channel layer 140 on the first cell region insulating layer 191, a portion of the buried insulating layers 160 may be then removed from a level of the upper surface of the first cell region insulating layer 191 by a predetermined depth of the channel holes CHH. When the predetermined depth is equal to the protrusion length h2 of the protruding region 145, the portion of the buried insulating layer 160 may be removed to contact a lower surface S1 of the protruding region 145, and such that a level of an upper surface of the buried insulating layer 160 is equal to a level of the lower surface S1 of the protruding region 145. When the predetermined depth at which the buried insulating layer 160 is removed is longer than the protrusion length h2 of the protruding region 145, the semiconductor device 100c illustrated in FIG. 6 may be provided, and conversely, when the predetermined depth is shorter than the protrusion length h2 of the protruding region 145, the semiconductor device 100d illustrated in FIG. 7 may be provided. In this manner, the buried insulating layers 160 in each of the channel holes CHH may form a space on an upper end thereof while exposing at least a portion of a side surface of the protruding region 145 of the channel layer 140.

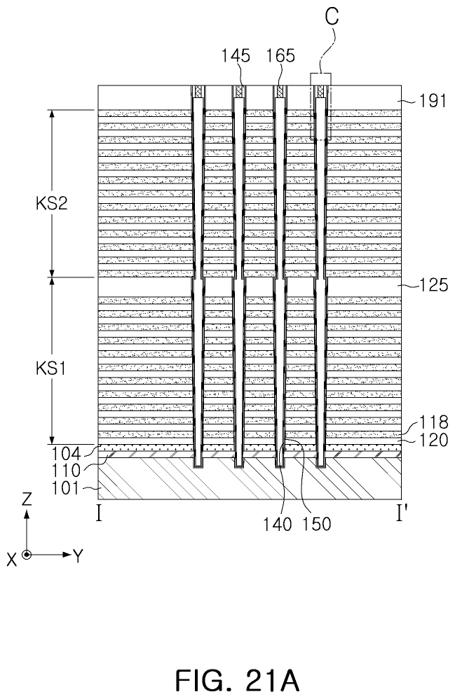

As illustrated in FIGS. 11, 21A, and 21B, center pad layers 165 may be formed in the channel holes CHH to prepare channel structures CH (S210). A center pad layer 165 may be formed by filling a space on the buried insulating layer 160 on an upper end of the channel holes CHH and depositing a conductive material on the channel layer 140. The central pad layer 165 may be formed of a conductive material, and may have a different crystalline quality from the channel layer 140. For example, the central pad layer 165 may be formed of polycrystalline silicon. Next, a chemical mechanical polishing (CMP) process may be performed on the polycrystalline silicon until the upper surface of the first cell region insulating layer 191 is exposed, and, as illustrated in FIG. 21B, the center pad layer 165 and the first cell region may be limitedly formed in the channel hole CHH such that the central pad layer 165 is coplanar with the cell region insulating layer 191.

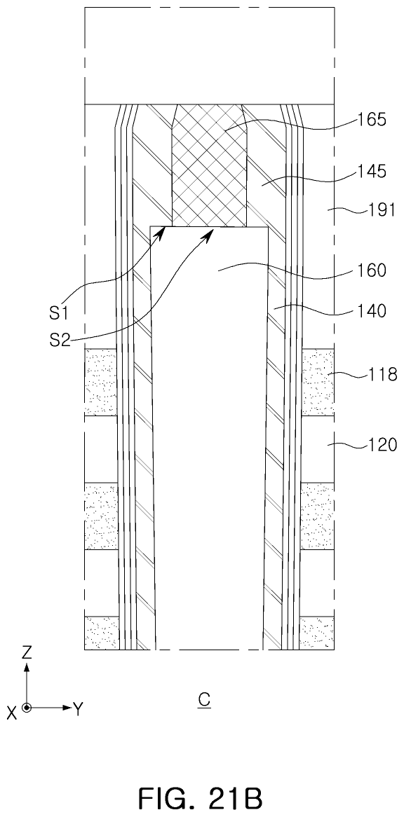

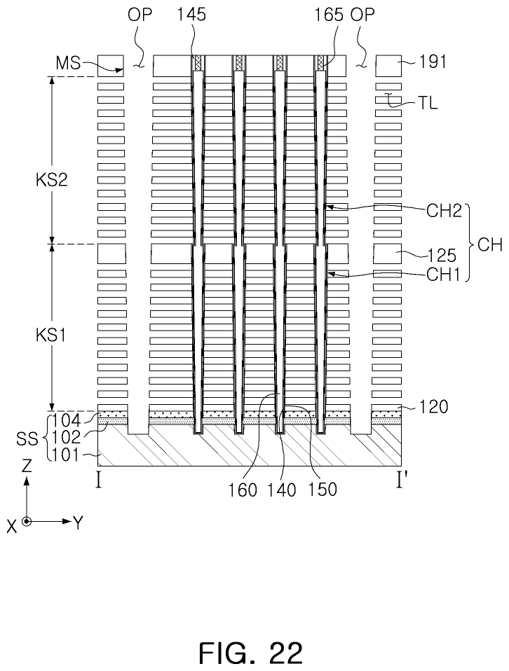

As in FIGS. 11 and 22, openings OP passing through the first and second mold structures KS1 and KS2 may be formed, a first horizontal conductive layer 102 may be formed, and the sacrificial insulating layers 118 may be removed to form tunnel portions TL (S220). The openings OP may be formed from the first cell region insulating layer 191. The openings OP may be formed to penetrate the first and second mold structures KS1 and KS2, penetrate the second horizontal conductive layer 104 in a lower portion, and extend in the X-direction.

Next, separate sacrificial spacer layers may be formed in the openings OP, an etch-back process may be performed to expose the horizontal sacrificial layer 110, and the horizontal sacrificial layer 110 may be removed from an exposed region. The horizontal sacrificial layer 110 may be removed by, for example, a wet etching process. During the removal process of the horizontal sacrificial layer 110, a portion of the channel dielectric layer 150 exposed in a region from which the horizontal sacrificial layer 110 was removed may also be removed. After forming the first horizontal conductive layer 102 by depositing a conductive material in a region from which the horizontal sacrificial layer 110 was removed, the sacrificial spacer layers may be removed in the openings OP. In this process, a source structure SS including the plate layer 101 and the first and second horizontal conductive layers 102 and 104 may be formed. The sacrificial insulating layers 118 may be removed selectively with respect to the interlayer insulating layers 120 using, for example, wet etching. Therefore, a plurality of tunnel portions TL may be formed between the interlayer insulating layers 120.

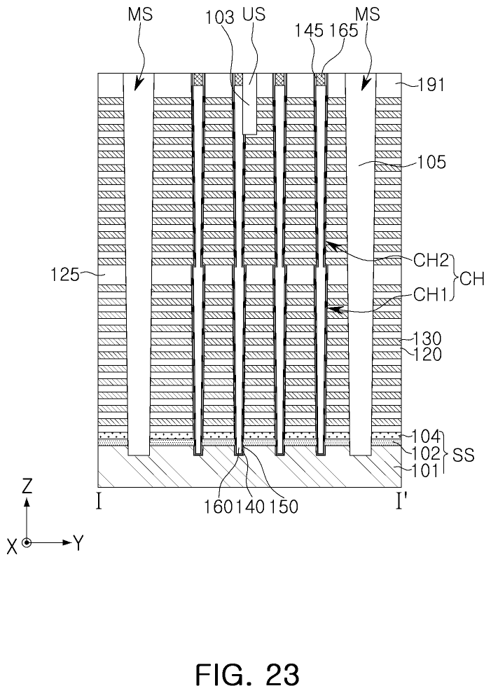

Referring to FIGS. 11 and 23, gate electrodes 130 may be formed by filling the tunnel portions TL with a conductive material (S230), and a separation insulating layer 105 may be formed. First, the material may form a horizontal blocking layer 158 (see FIG. 3) in the tunnel portions TL. The conductive material forming the gate electrodes 130 may fill the tunnel portions TL. The conductive material may include a metal material, a polycrystalline silicon material, or a metal silicide material. After forming the gate electrodes 130, the conductive material deposited in the openings OP may be removed by an additional process to form the separation insulating layer 105. In this case, etching for forming an upper separation structure US may be additionally performed, and this may be performed while removing a portion of the channel structure CH. Therefore, an upper separation insulating layer 103 may also be formed simultaneously with the separation insulating layer 105.

Next, referring to FIG. 2 together, a second cell region insulating layer 192 may be further formed on the channel structure CH, and contact plugs 170 passing through the same and connected to the channel structures CH may be formed to manufacture the semiconductor device 100.

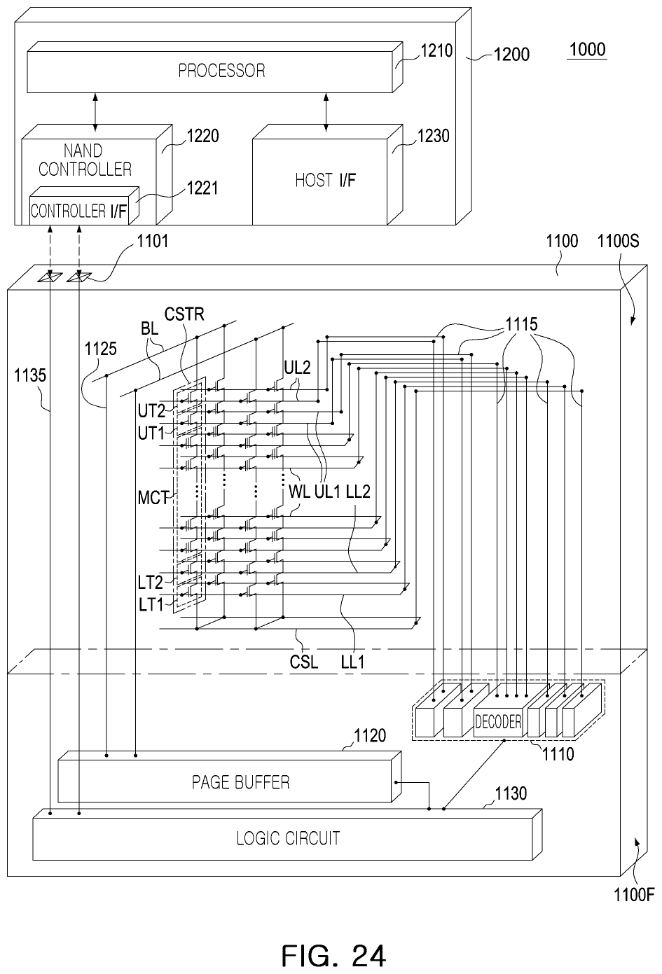

FIG. 24 is a view schematically illustrating a data storage system including a semiconductor device according to example embodiments. Referring to FIG. 24, a data storage system 1000 may include a semiconductor device 1100, and a controller 1200 electrically connected to the semiconductor device 1100. The data storage system 1000 may be a storage device including the semiconductor device 1100 as a single semiconductor device or a plurality of semiconductor devices, or an electronic device including the storage device. For example, the data storage system 1000 may be a solid state drive device (SSD), a universal serial bus (USB), a computing system, a medical device, or a communication device, including the semiconductor device 1100 as a single semiconductor device or a plurality of semiconductor devices.

The semiconductor device 1100 may be a non-volatile memory device, for example, a NAND flash memory device described above with reference to FIGS. 1 to 10. The semiconductor device 1100 may include a first semiconductor structure 1100F, and a second semiconductor structure 1100S on the first semiconductor structure 1100F. In example embodiments, the first semiconductor structure 1100F may be disposed next to the second semiconductor structure 1100S. The first semiconductor structure 1100F may be a peripheral circuit structure including a decoder circuit 1110, a page buffer 1120, and a logic circuit 1130. The second semiconductor structure 1100S may be a memory cell structure including bit lines BL, a common source line CSL, word lines WL, first and second upper gate lines UL1 and UL2, first and second lower gate lines LL1 and LL2, and memory cell strings CSTR between each of the bit lines BL and the common source line CSL.

In the second semiconductor structure 1100S, each of the memory cell strings CSTR may include lower transistors LT1 and LT2 adjacent to the common source line CSL, upper transistors UT1 and UT2 adjacent to each of the bit lines BL, and a plurality of memory cell transistors MCT disposed between each of the lower transistors LT1 and LT2 and each of the upper transistors UT1 and UT2. The number of lower transistors LT1 and LT2 and the number of upper transistors UT1 and UT2 may be variously changed according to embodiments.

In example embodiments, each of the upper transistors UT1 and UT2 may include a string select transistor, and each of the lower transistors LT1 and LT2 may include a ground select transistor. The lower gate lines LL1 and LL2 may be gate electrodes of the lower transistors LT1 and LT2, respectively. The word lines WL may be gate electrodes of the memory cell transistors MCT, and the upper gate lines UL1 and UL2 may be gate electrodes of the upper transistors UT1 and UT2, respectively.

In example embodiments, the lower transistors LT1 and LT2 may include a lower erase control transistor LT1 and a ground select transistor LT2, connected in series. The upper transistors UT1 and UT2 may include a string select transistor UT1 and an upper erase control transistor UT2, connected in series. At least one of the lower erase control transistor LT1 or the upper erase control transistor UT2 may be used for an erase operation of erasing data stored in the memory cell transistors MCT using a gate-induced-drain-leakage (GIDL) phenomenon.

The common source line CSL, the first and second lower gate lines LL1 and LL2, the word lines WL, and the first and second upper gate lines UL1 and UL2 may be electrically connected to the decoder circuit 1110 through first connection wirings 1115 extending from the first semiconductor structure 1100F into the second semiconductor structure 1100S. The bit lines BL may be electrically connected to the page buffer 1120 through second connection wirings 1125 extending from the first semiconductor structure 1100F into the second semiconductor structure 1100S.

In the first semiconductor structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through input/output connection wirings 1135 extending from the first semiconductor structure 1100F into the second semiconductor structure 1100S.

The controller 1200 may include a processor 1210, a NAND controller 1220, and a host interface 1230. According to embodiments, the data storage system 1000 may include a plurality of semiconductor devices 1100, and in this case, the controller 1200 may control the plurality of semiconductor devices 1100. The processor 1210 may control an overall operation of the data storage system 1000 including the controller 1200. The processor 1210 may operate according to a predetermined firmware, and may access to the semiconductor device 1100 by controlling the NAND controller 1220. The NAND controller 1220 may include a controller interface 1221 processing communications with the semiconductor device 1100. A control command for controlling the semiconductor device 1100, data to be written to the memory cell transistors MCT of the semiconductor device 1100, data to be read from the memory cell transistors MCT of the semiconductor device 1100, or the like may be transmitted through the controller interface 1221. The host interface 1230 may provide a communication function between the data storage system 1000 and an external host. When a control command is received from the external host through the host interface 1230, the processor 1210 may control the semiconductor device 1100 in response to the control command.

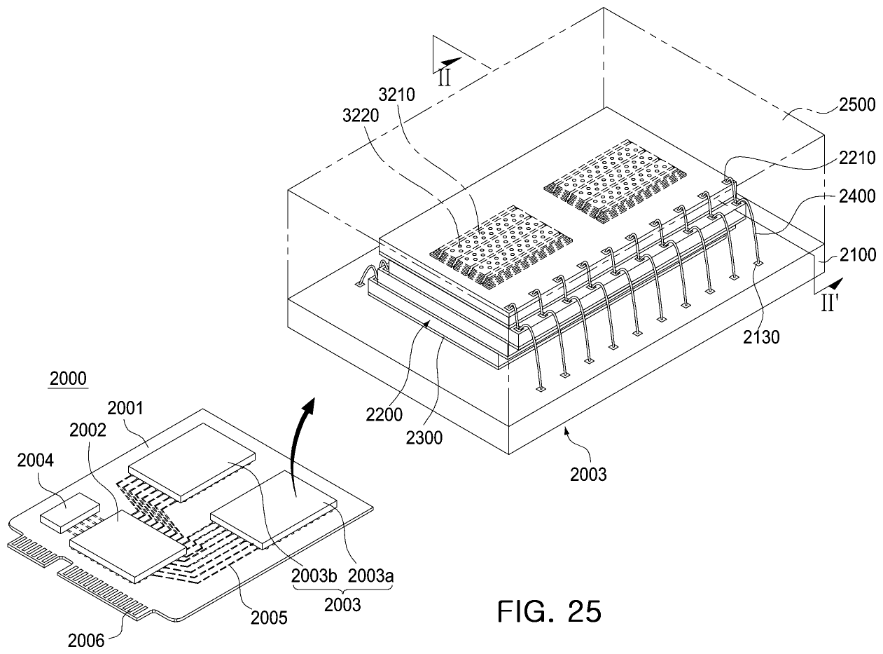

FIG. 25 is a perspective view schematically illustrating a data storage system including a semiconductor device according to example embodiments. Referring to FIG. 25, a data storage system 2000 according to an example embodiment may include a main substrate 2001, a controller 2002 mounted on the main substrate 2001, at least one semiconductor package 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins, which may be coupled to an external host. The number and arrangement of the plurality of pins in the connector 2006 may be changed according to a communication interface between the data storage system 2000 and the external host. In example embodiments, the data storage system 2000 may be communicated with the external host according to any one interface of a universal serial bus (USB), peripheral component interconnect express (PCI-Express), serial advanced technology attachment (SATA), M-Phy for universal flash storage (UFS), or the like. In example embodiments, the data storage system 2000 may be operated by power supplied from the external host through the connector 2006. The data storage system 2000 may further include a power management integrated circuit (PMIC) distributing power, supplied from the external host, to the controller 2002 and the semiconductor package 2003.

The controller 2002 may write data to the semiconductor package 2003 or read data from the semiconductor package 2003, and may improve an operation speed of the data storage system 2000.

The DRAM 2004 may be a buffer memory reducing a difference in speed between the semiconductor package 2003, which may be a data storage space, and the external host. The DRAM 2004 included in the data storage system 2000 may also operate as a type of cache memory, and may provide a space temporarily storing data in a control operation on the semiconductor package 2003. When the DRAM 2004 is included in the data storage system 2000, the controller 2002 may further include a DRAM controller controlling the DRAM 2004 in addition to a NAND controller controlling the semiconductor package 2003.

The semiconductor package 2003 may include first and second semiconductor packages 2003a and 2003b, spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting each of the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210. The input/output pad 2210 may correspond to the input/output pad 1101 of FIG. 24. Each of the semiconductor chips 2200 may include gate stack structures 3210 and channel structures 3220. Each of the semiconductor chips 2200 may include the semiconductor device described above with reference to FIGS. 1 to 10.

In example embodiments, the connection structure 2400 may be a bonding wire electrically connecting the input/output pad 2210 and the upper package pads 2130. Therefore, in each of the first and second semiconductor packages 2003a and 2003b, the semiconductor chips 2200 may be electrically connected to each other by a bonding wire process, and may be electrically connected to the package upper pads 2130 of the package substrate 2100. According to embodiments, in each of the first and second semiconductor packages 2003a and 2003b, the semiconductor chips 2200 may be electrically connected to each other by a connection structure including a through silicon via (TSV), instead of a connection structure 2400 by a bonding wire process.

In example embodiments, the controller 2002 and the semiconductor chips 2200 may be included in one (1) package. In an example embodiment, the controller 2002 and the semiconductor chips 2200 may be mounted on a separate interposer substrate, different from the main substrate 2001, and the controller 2002 and the semiconductor chips 2200 may be connected to each other by a wiring formed on the interposer substrate.

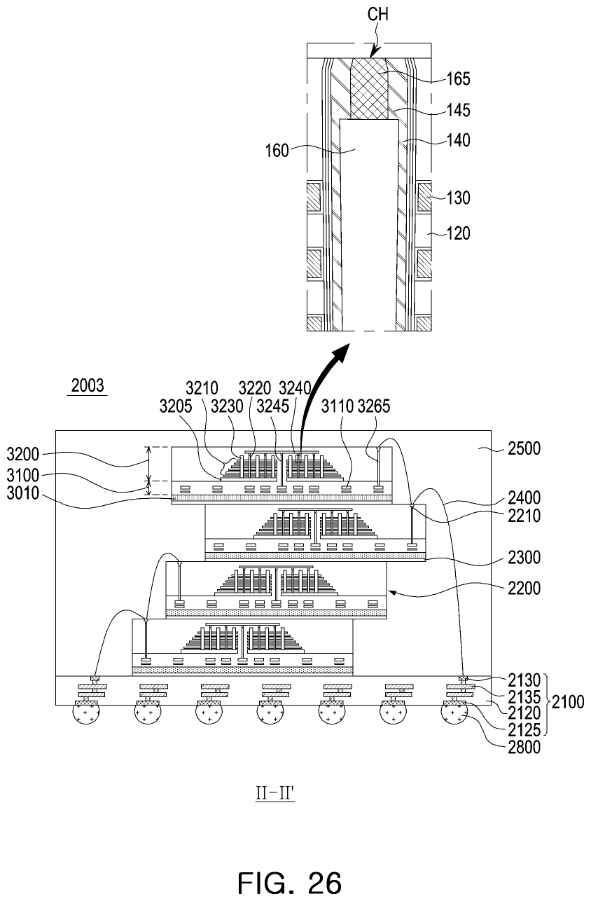

FIG. 26 is a cross-sectional view schematically illustrating a semiconductor package according to example embodiments. FIG. 26 illustrates an example embodiment of the semiconductor package 2003 of FIG. 25, and conceptually illustrates a region taken along line II-II′ of the semiconductor package 2003 of FIG. 25. Referring to FIG. 26, in the semiconductor package 2003, the package substrate 2100 may be a printed circuit board. The package substrate 2100 may include a package substrate body portion 2120, upper pads 2130 (refer to FIG. 26) disposed on an upper surface of the package substrate body portion 2120, lower pads 2125 disposed on a lower surface of the package substrate body portion 2120 or exposed from the lower surface, and internal wirings 2135 electrically connecting the upper pads 2130 and the lower pads 2125 in the package substrate body portion 2120. The upper pads 2130 may be electrically connected to the connection structures 2400. The lower pads 2125 may be connected to the wiring patterns 2005 of the main substrate 2001 of the data storage system 2000, as illustrated in FIG. 26, through conductive connection portions 2800.

Each of the semiconductor chips 2200 may include a semiconductor substrate 3010, and a first semiconductor structure 3100 and a second semiconductor structure 3200, sequentially stacked on the semiconductor substrate 3010. The first semiconductor structure 3100 may include a peripheral circuit region including peripheral wirings 3110. The second semiconductor structure 3200 may include a common source line 3205, a gate stack structure 3210 on the common source line 3205, channel structures 3220 and separation regions 3230, passing through the gate stack structure 3210, bit lines 3240 electrically connected to the channel structures 3220, and cell contact plugs 3235 electrically connected to word lines WL (see FIG. 24) of the gate stack structure 3210. As described above with reference to FIGS. 1 to 10, in each of the semiconductor chips 2200, channel layers 140 in channel structures CH may include a protruding region 145 in an upper portion to increase a width thereof, and the channel layer 140 may be formed as a single crystal material layer.

Each of the semiconductor chips 2200 may include a through-interconnection 3245 electrically connected to the peripheral wirings 3110 of the first semiconductor structure 3100 and extending into the second semiconductor structure 3200. The through-interconnection 3245 may be disposed outside the gate stack structure 3210, and may further be disposed to pass through the gate stack structure 3210. Each of the semiconductor chips 2200 may further include an input/output pad 2210 (see FIG. 25) electrically connected to the peripheral wirings 3110 of the first semiconductor structure 3100.

According to the present inventive concept, sufficient metal particles that may crystallize entirely a channel layer in each channel hole into a single crystal may be provided by stacking an amorphous seed layer on an upper portion of the channel layer and performing a MILC process through the metal particles on the amorphous seed layer, to provide a semiconductor device and a data storage system, having improved reliability.

Various advantages and effects of the present inventive concept are not limited to the above-described content, and can be more easily understood through description of specific embodiments of the present inventive concept.

While example embodiments have been illustrated and described above, it will be apparent to those skilled in the art that modifications and variations could be made without departing from the scope of the present inventive concept as defined by the appended claims.

1. A semiconductor device, comprising:
a substrate;
a stack structure having a plurality of spaced-apart gate electrodes therein and extending in a vertical direction perpendicular to an upper surface of the substrate; and
a plurality of channel structures extending vertically within respective channel holes, which pass vertically through the stack structure, with each of said channel structures comprising:
a channel layer having a first crystal structure, and extending from adjacent an upper end to adjacent a lower end of a corresponding one of the channel holes;
a protruding region extending from adjacent the upper end of each of the channel holes in the vertical direction, protruding from the channel layer toward a central axis of each of the channel holes, and having a second crystal structure; and
a central pad layer extending inside the protruding region and having a third crystal structure, which is different from the first crystal structure.

2. The device of claim 1, wherein a size of a crystal grain of the channel layer is larger than a size of a crystal grain of the central pad layer.

3. The device of claim 1, wherein a size of a crystal grain of the protruding region is larger than a size of a crystal grain of the central pad layer.

4. The device of claim 1, wherein the first crystal structure of the channel layer is identical to the second crystal structure of the protruding region.

5. The device of claim 1, wherein a thickness of the protruding region is equal to or greater than a thickness of the channel layer.

6. The device of claim 1, wherein the channel layer comprises single crystal silicon, whereas the central pad layer comprises polycrystalline silicon.

7. The device of claim 1, wherein a length of the protruding region is smaller than a length of the channel layer, as measured in the vertical direction.

8. The device of claim 1, wherein a lower surface of the protruding region is located on a level equal to a level of a lower surface of the central pad layer.

9. The device of claim 1, wherein a lower surface of the protruding region is located on a level lower than a level of a lower surface of the central pad layer.

10. The device of claim 1, wherein a lower surface of the protruding region is located on a level higher than a level of a lower surface of the central pad layer.

11. The device of claim 1, wherein a lower surface of the protruding region is located on a level lower than a level of a lower surface of an uppermost gate electrode among the gate electrodes.

12. The device of claim 1, wherein the first crystal structure of the channel layer is different from the second crystal structure of the protruding region.

13. The device of claim 1, further comprising a buried insulating layer extending inside the channel layer and having an upper surface in contact with a lower surface of the central pad layer.

14. The device of claim 1, wherein the second crystal structure of the protruding region is different from the third crystal structure of the central pad layer.

15. A data storage system, comprising:
a semiconductor storage device including: a first semiconductor structure having circuit elements therein, a second semiconductor structure extending on one surface of the first semiconductor structure, and an input/output pad electrically connected to the circuit elements; and
a controller electrically connected to the semiconductor storage device through the input/output pad, and configured to control the semiconductor storage device;
wherein the second semiconductor structure includes:
a substrate;
a stack structure including gate electrodes spaced apart from each other in a first direction that is perpendicular to an upper surface of the substrate; and
channel structures extending vertically in corresponding channel holes that pass vertically through the stack structure;
wherein each of the channel structures includes:
a channel layer connected from an upper end to a lower end of each of the channel holes, and including a single crystal conductive material; and
a central pad layer extending from the upper end of each of the channel holes in the first direction to fill an internal space of the channel layer, and including a polycrystalline conductive material; and
wherein a first thickness of the channel layer in a second direction perpendicular to the first direction, and on the upper end of each of the channel holes is greater than a second thickness of the channel layer in the second direction on the lower end of each of the channel holes.

16. The system of claim 15, wherein the channel layer has a stepped surface changing from the first thickness to the second thickness; and wherein a level of the stepped surface is identical to a level of a lower surface of the central pad layer.

17. The system of claim 15, wherein the channel layer has a stepped surface changing from the first thickness to the second thickness; and wherein a level of the stepped surface is different from a level of a lower surface of the central pad layer.

18.-20. (canceled)

21. A semiconductor device, comprising:
a substrate;
a stack structure including gate electrodes spaced apart from each other in a first direction, which is perpendicular to an upper surface of the substrate; and
channel structures that extend vertically in corresponding channel holes that pass vertically through the stack structure and respectively comprise:
a channel layer connected from adjacent an upper end to adjacent a lower end of each of the channel holes, including a protruding region protruding from the upper end of each of the channel holes in a second direction perpendicular to the first direction, and including a single crystal structure; and
a central pad layer extending inside the protruding region and including a polycrystalline structure.

22. The device of claim 21, wherein a thickness of the protruding region is equal to or greater than a thickness of a lower end of the channel layer.

23. The device of claim 21, wherein the protruding region is in contact with an outer sidewall of the central pad layer, and has a ring shape.

24.-30. (canceled)
